(19) United States
(12) Patent Application Publication
(10) Pub. No.: US 2026/0156882 A1
(43) Pub. Date: Jun. 4, 2026

(54) COMPLEMENTARY FIELD-EFFECT TRANSISTOR AND MANUFACTURING METHOD THEREOF

(71) Applicant: TAIWAN SEMICONDUCTOR MANUFACTURING COMPANY, LTD., Hsinchu (TW)

(72) Inventors: Meng-Yu LIN, New Taipei City (TW); Chun-Fu CHENG, Hsinchu County (TW); Sean MA, Hsinchu City (TW)

(73) Assignee: TAIWAN SEMICONDUCTOR MANUFACTURING COMPANY, LTD., Hsinchu (TW)

(21) Appl. No.: 18/965,644

(22) Filed: Dec. 2, 2024

(51) Int. Cl. H10D 62/13; H10D 30/00; H10D 30/01; H10D 30/40; H10D 30/67; H10D 62/10; H10D 64/01; H10D 84/01; H10D 84/85

(52) U.S. Cl. CPC H10D 62/151; H10D 30/014; H10D 30/019; H10D 30/40; H10D 30/501; H10D 30/6735; H10D 62/121; H10D 64/017; H10D 84/0167; H10D 84/017; H10D 84/85

(57) ABSTRACT

This disclosure provides enhancements in semiconductor fabrication aimed at boosting device performance and simplifying manufacturing. By employing a dopant layer, such as borosilicate or phosphosilicate glass, low doping junction diffusion can be managed effectively. An advancement can include using silicon germanium (SiGe) as an inner spacer for continuous sidewall epitaxial (EPI) growth seeding, optimizing the epitaxial source/drain layer quality by maintaining a thin, highly-doped layer to control electrical properties. Additional improvement can include filling stress material between the epitaxial source/drain sidewalls to preserve channel stress and enhance electrical performance. Furthermore, gate and inner spacers can be removed, creating air-filled structures that improve cell capacitance. Moreover, an inner wrap-around contact (WAC) can be formed using high etch selectivity between the stress material and epitaxial layers, reducing contact resistance and preventing deep metal-defined recess processes.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of a semiconductor structure in accordance with some embodiments of the present disclosure

FIGS. 2-27 illustrate schematic views of intermediate stages in the manufacturing of complementary field-effect transistors (CFETs) in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure in various embodiments provides several features aimed at enhancing device performance and manufacturability. A dopant layer, such as borosilicate glass layer or phosphosilicate glass layer, can be employed to manage low doping junction diffusion effectively, eliminating the need for proximity push or convex processes and thereby simplifying manufacturing steps. An improvement can be the use of a semiconductive material, such as silicon germanium (SiGe), as an inner spacer for continuous sidewall epitaxial (EPI) growth seeding, which in turn enhances the quality of the epitaxial source/drain layer by maintaining a thin layer with high doping concentrations to control electrical properties. Further improvement can include filling stress material between sidewalls of the epitaxial source/drain layers to maintain channel stress without merging the epitaxial layers, which in turn compensates for loss in channel stress, enhancing the electrical performance of n-type and p-type networks respectively. After the mechanical chemical polishing (CMP) of the Metal Gate (MG), gate spacer and inner spacer can be removed, leading to the creation of air-filled spacer structures, which contribute to over an improvement in cell capacitance. Furthermore, an inner wrap-around contact (WAC), which can be made by the high etch selectivity between the stress material and epitaxial layers, can be formed to reduce contact resistance and prevent deep metal-defined recess processes.

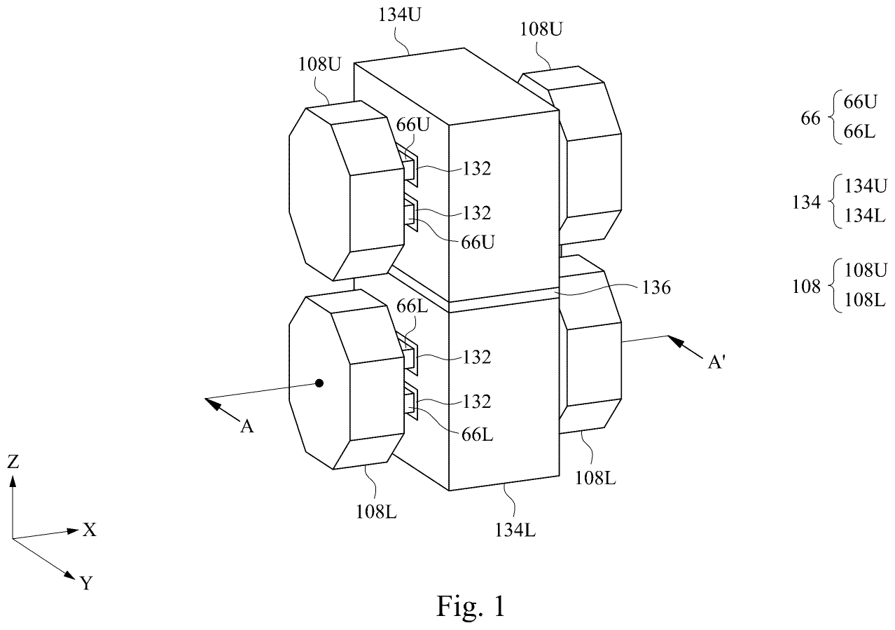

Reference is made to FIG. 1. FIG. 1 illustrates an example of a CFET schematic, in accordance with some embodiments. FIG. 1 is a three-dimensional view, where some features of the CFETs are omitted for illustration clarity. The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (e.g., isolation layer 136) may be used to separate and electrically isolate the upper semiconductor nanostructures 66U from the lower semiconductor nanostructures 66L.

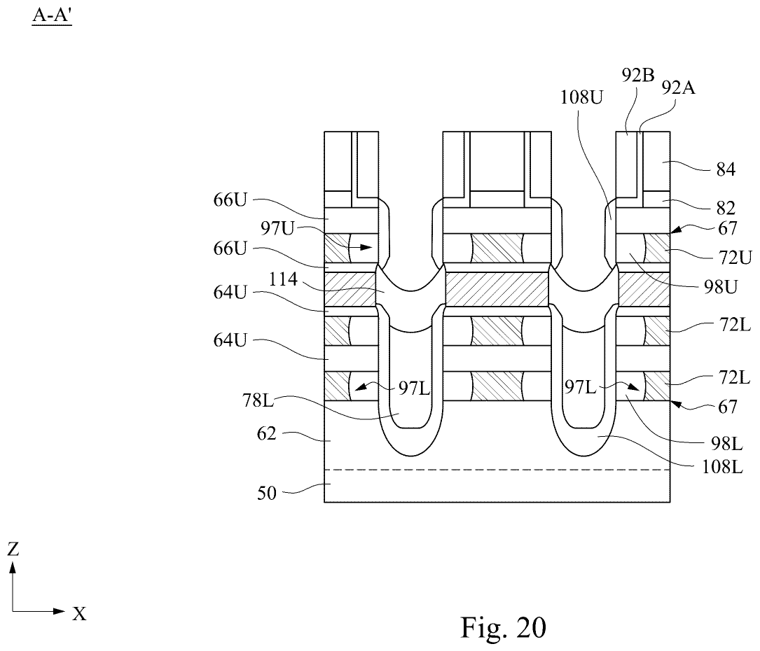

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108U/108L may refer to a source or a drain, individually or collectively dependent upon the context. Isolation features (e.g., isolation dielectric 114 as shown in FIG. 20) may be formed to separate desired ones of the source/drain regions 108 and/or desired ones of the gate electrodes 134. For example, a lower gate electrode 134L may optionally be separated from an upper gate electrode 134U by an isolation layer 136. Alternatively, a lower gate electrode 134L may be coupled to an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Subsequent figures refer to these reference cross-sections for clarity.

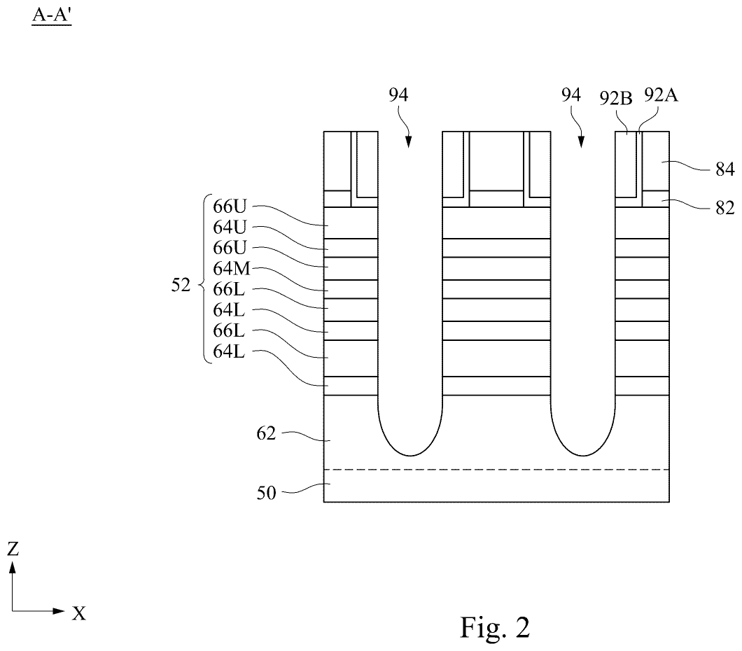

Reference is made to FIGS. 2-27. FIGS. 2-27 illustrate schematic views of intermediate stages in the manufacturing of CFETs in accordance with some embodiments. Specifically, FIGS. 2-27 illustrate cross-sectional views along a similar cross-section as reference cross-section A-A′ in FIG. 1.

Reference is made to FIG. 2. A substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers (including lower dummy layers, a middle dummy layer, and upper dummy layers) and semiconductor layers (including lower semiconductor layers and upper semiconductor layers). The lower dummy layers and the lower semiconductor layers are disposed below the middle dummy layer. The upper dummy layers and the upper semiconductor layers are disposed above the middle dummy layer. As subsequently described in greater detail, the dummy layers will be removed and the semiconductor layers will be patterned to form channel regions of CFETs. Specifically, the lower semiconductor layers will be patterned to form channel regions of the lower nanostructure-FETs of the CFETs, and the upper semiconductor layers will be patterned to form channel regions of the upper nanostructure-FETs of the CFETs.

The dummy layers can be formed of a semiconductor material. The semiconductor material may be selected from the candidate semiconductor materials of the substrate 50. The material of the middle dummy layer may have a high etching selectivity to the material of the lower and upper dummy layers. As such, the material of the middle dummy layer may be removed at a faster rate than the material of the lower and upper dummy layers in subsequent processing. In some embodiments, the lower dummy layers, the middle dummy layer, and the upper dummy layers can be formed of silicon-germanium. When the lower dummy layers, the middle dummy layer, and the upper dummy layers are formed of silicon-germanium, the middle dummy layer may have a higher germanium concentration than the lower and upper dummy layers.

The semiconductor layers (including the lower semiconductor layers and upper semiconductor layers) can be formed of one or more semiconductor material(s). The semiconductor material(s) may be selected from the candidate semiconductor materials of the substrate 50. The lower semiconductor layers and the upper semiconductor layers may be formed of the same semiconductor material, or may be formed of different semiconductor materials. In some embodiments, the lower semiconductor layers and the upper semiconductor layers can both be formed of a semiconductor material suitable for p-type devices and n-type devices, such as silicon. In some embodiments, the lower semiconductor layers are formed of a semiconductor material suitable for p-type devices, such as germanium or silicon-germanium, and the upper semiconductor layers are formed of a semiconductor material suitable for n-type devices, such as silicon or silicon carbide. The semiconductor material(s) of the semiconductor layers have a high etching selectivity to the semiconductor material of the dummy layers. As such, the material of the dummy layers may be removed at a faster rate than the material of the semiconductor layers in subsequent processing. In some embodiments, the semiconductor layers are formed of silicon, which may be undoped or lightly doped at this step of processing.

The multi-layer stack 52 is illustrated as including four of the dummy layers and four of the semiconductor layers. It should be appreciated that the multi-layer stack 52 may include any number of the dummy layers and the semiconductor layers. The dummy layers and the semiconductor layers may be grown by a process such as vapor phase epitaxy (VPE) or molecular beam epitaxy (MBE), deposited by a process such as chemical vapor deposition (CVD) or atomic layer deposition (ALD), or the like.

As shown in FIG. 2, semiconductor fins 62 can be formed in the substrate 50. Additionally, nanostructures 64, 66 (including lower dummy nanostructures 64L, middle dummy nanostructure 64M, upper dummy nanostructures 64U, lower semiconductor nanostructures 66L, and upper semiconductor nanostructures 66U) can be formed in the multi-layer stack 52. In some embodiments, the nanostructures 64, 66 and the semiconductor fins 62 may be formed in the multi-layer stack 52 and the substrate 50 by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 and the isolation structures 68 by etching the multi-layer stack 52 may define the lower dummy nanostructures 64L from the lower dummy layers, the middle dummy nanostructure 64M from the middle dummy layer, the upper dummy nanostructures 64U from the upper dummy layers, the lower semiconductor nanostructures 66L from the lower semiconductor layers, and the upper semiconductor nanostructures 66U from the upper semiconductor layers. The lower dummy nanostructures 64L, the middle dummy nanostructure 64M, and the upper dummy nanostructures 64U may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, various one of the nanostructures 64, 66 will be removed to form channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs. The isolation structures 68 may define boundaries of the lower nanostructure-FETs and the upper nanostructure-FETs.

The semiconductor fins 62 and the nanostructures 64, 66 may be patterned by any suitable method. For example, the semiconductor fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the semiconductor fins 62 and the nanostructures 64, 66. In some embodiments, a mask (or other layer) may remain on the nanostructures 64, 66.

Although each of the semiconductor fins 62 and the nanostructures 64, 66 can be illustrated as having a constant width throughout, in other embodiments, the semiconductor fins 62 and/or the nanostructures 64, 66 may have tapered sidewalls such that a width of each of the semiconductor fins 62 and/or the nanostructures 64, 66 continuously increases in a direction towards the substrate 50. In such embodiments, each of the nanostructures 64, 66 may have a different width and be trapezoidal in shape.

As shown in FIG. 2, isolation regions can be formed adjacent the semiconductor fins 62. The isolation regions may be formed by depositing an insulating material over the substrate 50, the semiconductor fins 62, and nanostructures 64, 66, and between adjacent semiconductor fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 64, 66. Although the insulating material is illustrated as a single layer, some embodiments may utilize multiple layers. For example, in some embodiments a liner (not separately illustrated) may first be formed along a surface of the substrate 50, the semiconductor fins 62, and the nanostructures 64, 66. Thereafter, a fill material, such as one of the previously described insulating materials may be formed over the liner.

A removal process is then applied to the insulating material to remove excess insulating material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulating material are level after the planarization process is complete.

The insulating material is then recessed to form the isolation regions. The insulating material is recessed such that upper portions of the semiconductor fins 62 protrude from between neighboring isolation regions. Further, the top surfaces of the isolation regions may have a flat surface as illustrated, a convex surface, a concave surface (such as dishing), or a combination thereof. The top surfaces of the isolation regions may be formed flat, convex, and/or concave by an appropriate etch. The isolation regions may be recessed using an etching process, such as one that is selective to the insulating material (e.g., selectively etches the insulating material at a faster rate than the materials of the semiconductor fins 62 and the nanostructures 64, 66). For example, an oxide removal using, for example, dilute hydrofluoric (dHF) acid may be used.

As shown in FIG. 2, a dummy dielectric layer can be formed on the semiconductor fins 62 and/or the nanostructures 64, 66. The dummy dielectric layer may be, for example, silicon oxide, silicon nitride, a combination thereof, or the like, and may be deposited or thermally grown according to acceptable techniques. A dummy gate layer can be formed over the dummy dielectric layer, and a mask layer can be formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be formed of other materials that have a high etching selectivity to insulating materials. The mask layer may include, for example, silicon nitride, silicon oxynitride, or the like. In the illustrated embodiment, the dummy dielectric layer covers the isolation regions, such that the dummy dielectric layer extends between the dummy gate layer and the isolation regions. In another embodiment, the dummy dielectric layer covers only the semiconductor fins 62 and/or the nanostructures 64, 66.

Subsequently, the mask layer may be patterned using acceptable photolithography and etching techniques to form masks. The pattern of the masks then may be transferred to the dummy gate layer and to the dummy dielectric layer to form dummy gates 84 and dummy dielectrics 82, respectively. The dummy gates 84 cover respective channel regions of the nanostructures 64, 66. The pattern of the masks may be used to physically separate each of the dummy gates 84 from adjacent dummy gates 84. The dummy gates 84 may also have a lengthwise direction substantially perpendicular to the lengthwise direction of respective semiconductor fins 62. The masks can optionally be removed after patterning, such as by any acceptable etching technique.

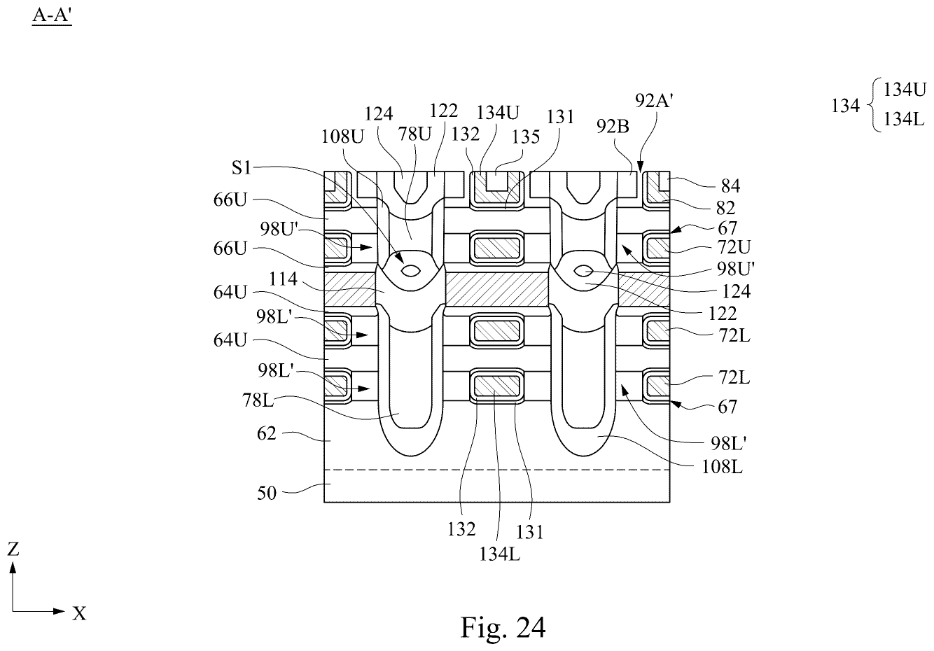

As shown in FIG. 2, first and second spacer layers can be conformally formed over the structure, in accordance with some embodiments. The first and second spacer layers can be formed over the nanostructures 64/66 and the dummy gates 84. The first and second spacer layers can be also formed on exposed sidewalls of the dummy gates 84, the dielectric liner 42, the nanostructures 64/66, and/or the fins 62. The first spacer layer or the second spacer layer may be formed of one or more dielectric material(s). The dielectric material may be silicon nitride, silicon oxynitride, or the like. Other low-dielectric constant (low-k) materials having a k-value less than about 3.5 may be utilized. The material of the first spacer layer can have a high etching selectivity to the material of the second spacer layer. As such, the material of the first spacer layer may be removed at a faster rate than the material of the second spacer layer in subsequent processing (see FIG. 24). In some embodiments, the first spacer layer can be formed of polymer, and the second spacer layer can be formed of a silicon-containing dielectric material. FIG. 2 shows two spacer layers of dielectric materials, but in other embodiments the first spacer layer may be formed of more layers. Acceptable dielectric materials may include silicon oxide, silicon nitride, silicon oxynitride, silicon oxycarbonitride, or the like, which may be formed by a deposition process such as CVD, ALD, or the like. Other dielectric materials formed by any acceptable process may be used. The spacer layers are subsequently etched to form spacers.

The spacer layers can be patterned to form gate spacers 92A and 92B, in accordance with some embodiments. Any acceptable etching process, such as a dry etch, a wet etch, the like, or a combination thereof, may be performed to pattern the spacer layers. The etching may be anisotropic. The spacer layers, when etched, can have portions left on the sidewalls of the dummy gates 84 (thus forming the gate spacers 92A and 92B). After etching, the gate spacers 92A and 92B may have straight sidewalls or may have curved sidewalls. In some embodiments, the etching stops on the dummy gates 84. In other embodiments, the dummy gates 84 and/or the isolation regions formed adjacent the semiconductor fins 62 may also be etched when patterning the spacer layers. For example, the etching may recess portions of the dummy gates 84 between fins 62 and/or between gate spacers 92A and 90B, or may etch through the dummy gates 84 and recess portions of the isolation regions formed adjacent the semiconductor fins 62. The etching may stop on the hard mask 52, may recess (e.g., thin) the dummy gates 84, or may etch through the dummy gates 84, depending on the characteristics of the etching process used. The gate spacers 92A and 92B may have straight sidewalls (as illustrated) or may have curved sidewalls (not separately illustrated).

Source/drain recesses 94 are formed in the upper semiconductor nanostructures 66U, the upper dummy nanostructures 64U, the middle dummy nanostructures 64M, the lower semiconductor nanostructures 66U, and the lower dummy nanostructures 64U. Epitaxial source/drain regions will be subsequently formed in the source/drain recesses 94. The source/drain recesses 94 may be formed by etching the upper semiconductor nanostructures 66U, the upper dummy nanostructures 64U, the middle dummy nanostructures 64M, the lower semiconductor nanostructures 66U, and the lower dummy nanostructures 64L using anisotropic etching processes, such as RIE, NBE, or the like. The gate spacers 92A and 92B and the dummy gates 84 mask portions of the upper semiconductor nanostructures 66U, the upper dummy nanostructures 64U, the middle dummy nanostructures 64M, the lower semiconductor nanostructures 66U, and the lower dummy nanostructures 64U during the etching processes used to form the source/drain recesses 94. A single etch process or multiple etch processes may be used to etch each of the upper semiconductor nanostructures 66U, the upper dummy nanostructures 64U, the middle dummy nanostructures 64M, the lower semiconductor nanostructures 66U, and the lower dummy nanostructures 64U.

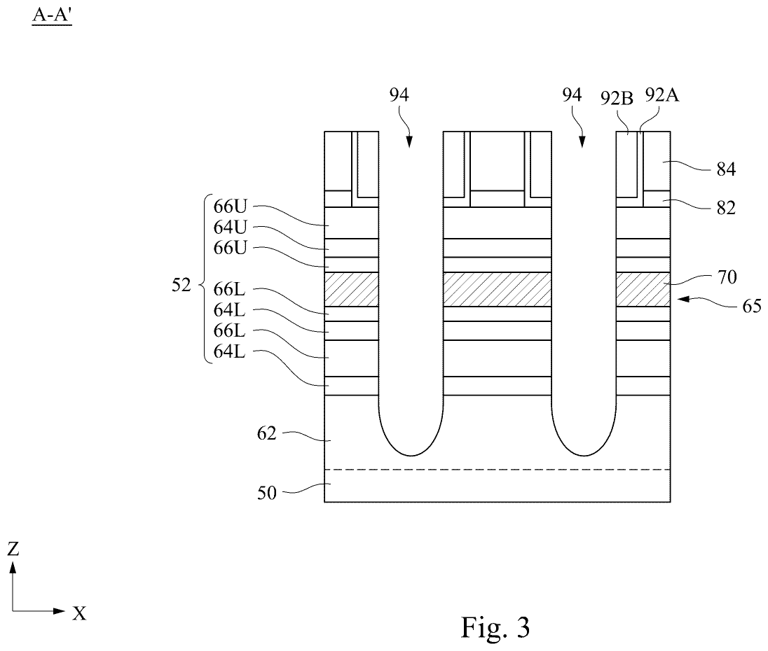

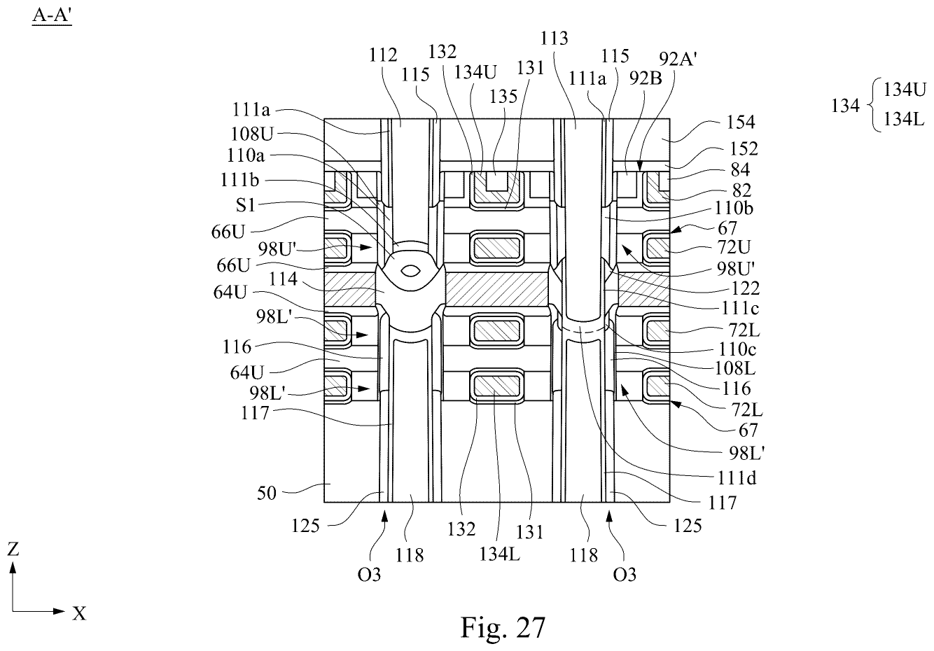

Reference is made to FIG. 3. The middle dummy nanostructures 64M are replaced with a dielectric material to form dielectric layers 70, in accordance with some embodiments. The dielectric layers 70 can serve as insulating barriers within semiconductor devices as shown in FIG. 27. In FIG. 3, the remaining portions of the middle dummy nanostructures 64M can be removed to form openings 65 in regions between the lower and upper semiconductor nanostructures 66L and 66U. The remaining portions of the middle dummy nanostructures 64M may be removed using an etching process that is performed through the source/drain recesses 96. The etching process may include any acceptable etching process that selectively etches the material of the middle dummy nanostructures 64M at a faster rate than the material of the lower and upper semiconductor nanostructures 66L and 66U, the lower and upper dummy nanostructures 64L and 64U, and/or the fins 62. The etching process may include a wet etch process and/or a dry etch process, and the etching may isotropic. In some embodiments, a trim process (not illustrated) is performed to decrease the thicknesses of the exposed portions of the lower and upper dummy nanostructures 64L and 64U and expand the openings 65.

Subsequently, the dielectric material can be deposited in the recesses 96 and in the openings 65, in accordance with some embodiments. The dielectric material may be deposited by a conformal deposition process, such as CVD, ALD, or the like. The dielectric material may comprise an insulating material such as silicon nitride or the like that can be selectively etched from the lower and upper dummy nanostructures 64L and 64U. The dielectric material may fill or overfill the openings 65 and may cover sidewalls of the lower and upper semiconductor nanostructures 66L and 66U and the lower and upper dummy nanostructures 64L and 64U. The dielectric material may cover top surfaces of the fins 62. In some embodiments, the dielectric material does not completely fill the source/drain recesses 96.

Subsequently, the dielectric material can be etched to form the dielectric layers 70. The etching may be isotropic or anisotropic. For example, the dielectric material may be etched using a wet etch process, such as dHF or the like. In some embodiments, the etching is performed until sidewalls of the dielectric material are recessed past (or flush with) sidewalls of the nanostructures 66.

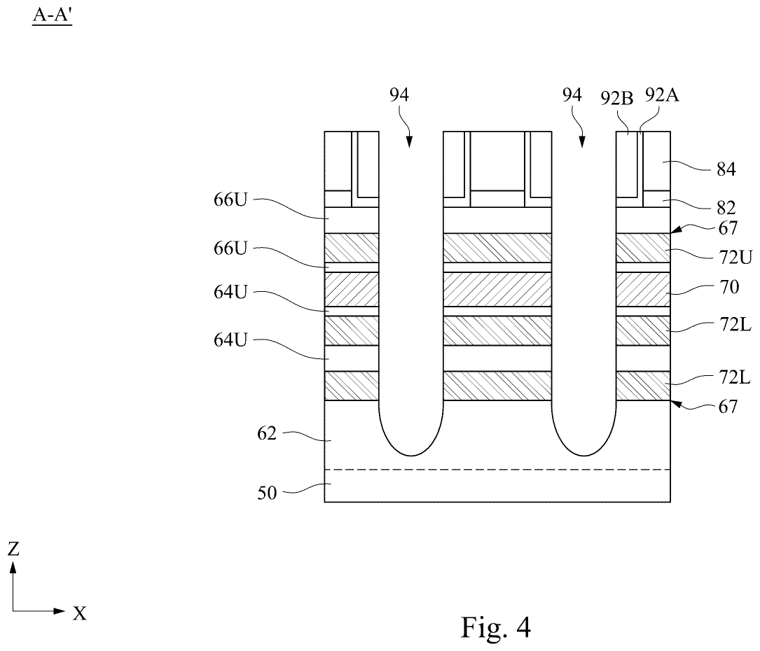

Reference is made to FIG. 4. The lower and upper dummy nanostructures 64L and 64U can be replaced with a dummy material to form lower and upper dummy regions 72L and 72U. In FIG. 4, the remaining portions of the lower and upper dummy nanostructures 64L and 64U can be removed to form openings 67 in regions between the lower and upper semiconductor nanostructures 66L and 66U. The remaining portions of the lower and upper dummy nanostructures 64L and 64U may be removed using an etching process that is performed through the source/drain recesses 96. The etching process may include any acceptable etching process that selectively etches the material of the lower and upper dummy nanostructures 64L and 64U at a faster rate than the material of the lower and upper semiconductor nanostructures 66L and 66U, the dielectric layers 70, and/or the fins 62. The etching process may include a wet etch process and/or a dry etch process, and the etching may isotropic. In some embodiments, a trim process (not illustrated) is performed to decrease the thicknesses of the exposed portions of the lower and upper semiconductor nanostructures 66L and 66U and expand the openings 67.

Subsequently, the dummy material is deposited to form the lower and upper dummy regions 72L and 72U, in accordance with some embodiments. In some cases, the dummy material may be considered a sacrificial material or a sacrificial oxide. In some cases, the lower and upper dummy regions 72L and 72U may be considered sacrificial regions, dielectric dummy regions, dummy nanostructures, dummy gate regions, or disposable oxide interposers (DOI). In subsequent source/drain formation steps, one or more high temperature processes may be performed to, for example, activate the dopants in the source/drain regions. When the material of the lower and upper dummy nanostructure 64L/64U (e.g., silicon germanium or the like) is exposed to high temperatures, germanium intermixing and increased roughness at interfaces between the lower and upper dummy nanostructures 64L and 64U and the lower and upper semiconductor nanostructures 66L and 66U may result. Such manufacturing defects may degrade the performance of the resulting transistor devices. For example, when germanium diffuses into the lower and upper semiconductor nanostructures 66L and 66U, germanium residue may remain in channel regions of the resulting transistor devices, which negatively affects the performance of the channel regions. Additionally, the intermixing may result in etching selective to either the lower and upper dummy nanostructures 64L and 64U or the lower and upper semiconductor nanostructures 66L and 66U to be less effective and less defined. This can result in, for example, portions of the lower and upper semiconductor nanostructures 66L and 66U being undesirably removed, which can damage features, reduce yield, and/or degrade device performance. By replacing the first nanostructures 64 with an insulating material (e.g., the dummy material) prior to the high temperature processes (e.g., source/drain annealing), manufacturing defects can be reduced and device performance can be improved. Additionally, the selectivity of etching between the dummy material and the material of the lower and upper semiconductor nanostructures 66L and 66U may be greater than the selectivity of etching between the lower and upper dummy nanostructures 64L and 64U and the lower and upper semiconductor nanostructures 66L and 66U, allowing for improved etching definition and less etching of the lower and upper semiconductor nanostructures 66L and 66U.

In some embodiments, the dummy material can be deposited in the recesses 96 and in the openings 67 by a conformal deposition process, such as CVD, ALD, or the like. The dummy material may comprise an insulating material such as silicon oxide or the like that can be selectively etched from the lower and upper semiconductor nanostructures 66L and 66U, the dielectric layer 70, and the fins 62. The dummy material may fill or overfill the openings 67 and may cover sidewalls of the lower and upper semiconductor nanostructures 66L and 66U. The dummy material may cover top surfaces of the fins 62. In some embodiments, the dummy material does not completely fill the source/drain recesses 96.

Subsequently, the dummy material can be etched to form the lower and upper dummy regions 72L and 72U. The etching may be isotropic or anisotropic. For example, the dummy material 71 may be etched using a wet etch process, such as dHF or the like. In some embodiments, the etching is performed until sidewalls of the dummy material are recessed past (or flush with) sidewalls of the lower and upper semiconductor nanostructures 66L and 66U.

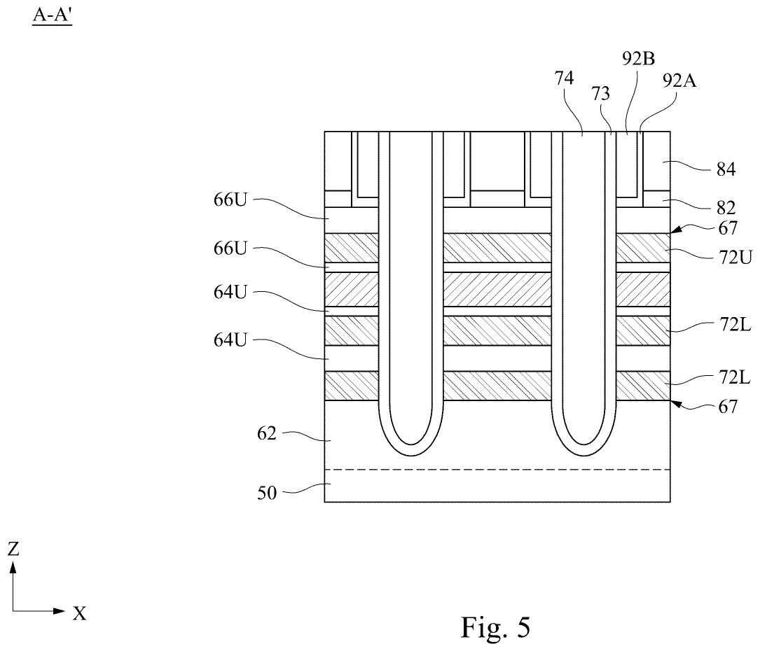

Reference is made to FIG. 5. A liner 73 can be deposited over the dummy gates 84 and in the source/drain recesses 96. In some embodiments, the liner may be formed of a semiconductor material selected from the candidate of silicon; germanium; a compound semiconductor including silicon carbide, gallium arsenide, gallium phosphide, indium phosphide, indium arsenide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, the liner 73 may be formed of a dielectric material, such as an oxide (e.g., silicon oxide), a nitride (e.g., as silicon nitride), the like, or a combination thereof. The liner 73 may be grown by a process such as vapor phase epitaxy (VPE) or molecular beam epitaxy (MBE), deposited by a process such as chemical vapor deposition (CVD) or atomic layer deposition (ALD), or the like.

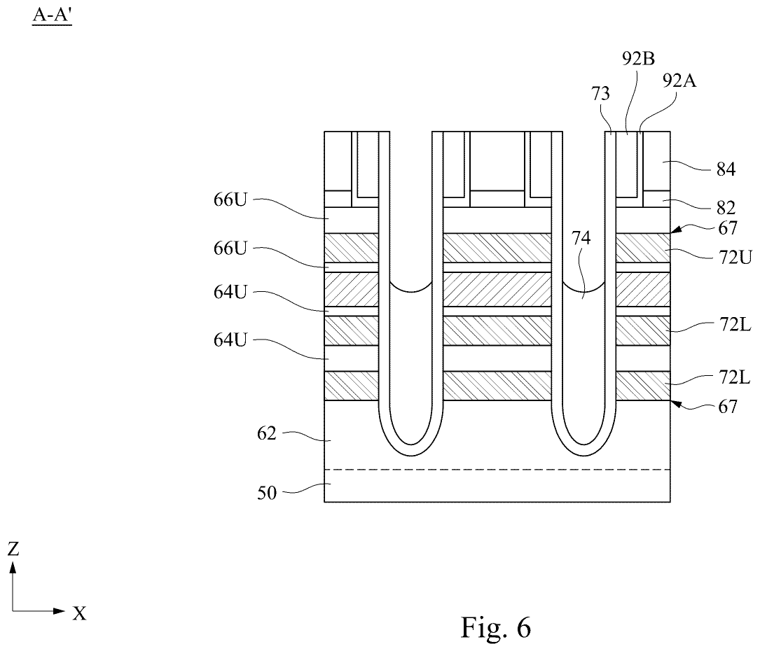

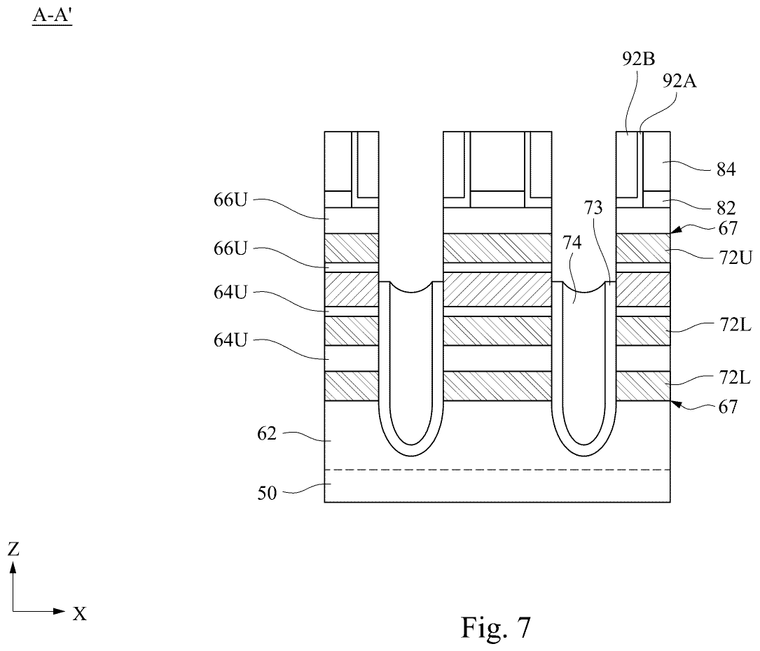

Subsequently, a dielectric layer 74 can be deposited over the liner 73 and in the source/drain recesses 96. In some embodiments, the dielectric layer 74 may be formed of a dielectric material, which may be deposited by any suitable method, such as CVD, PECVD, or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used. The material of the dielectric layer 74 may have a high etching selectivity to the material of the liner 73. As such, the material of the dielectric layer 74 may be removed at a different rate than the material of the liner 73 in subsequent processing as shown in FIGS. 6 and 7.

Subsequently, a removal process can be performed to level the top surfaces of the liner 73 and the dielectric layer 74 with the top surfaces of the gate spacers 92A and 92B and/or dummy gates 84. The removal process may include a planarization process such as a CMP process, a grinding process, an etch-back process, a combination thereof, or the like. After the planarization process, top surfaces of the liner 73, the dielectric layer 74, the gate spacers 92A and 92B, and the dummy gates 84 may be substantially level or coplanar (within process variations). Accordingly, the top surfaces of the dummy gates 84 may be exposed through the liner 73 and the dielectric layer 74.

Reference is made to FIG. 6. An etch back process can be performed on the dielectric layer 74 to scale down the dielectric layer 74. In some embodiments, the etch back process may include a bias plasma etching step. In some embodiments, the bias plasma etching step may use a gas mixture of Cl₂, O₂, BCl₃, and Ar with a bias in a range from about 25V to about 1200V. The bias plasma etching step may be performed to remove portions of the dielectric layer 74, such that portions of the source/drain recesses 96 may reappear with shallower depth. The top surfaces of the dielectric layers 74 may be no longer level with the top surfaces of the gate spacers 92A and 92B and/or dummy gates 84, and then inner sidewalls of the liner 73 can be then exposed from the dielectric layer 74. In some embodiment, the etch back process can be performed such that the top surface of the dielectric layer 74 can be at a level height between a bottom surface of the dielectric layer 70 and a top surface of the dielectric layer 70.

Reference is made to FIG. 7. Exposed portions of the liner 73 can be removed from the dielectric layer 74. In some embodiments, the exposed portions of the liner 73 can be removed in one or more etching steps. In some embodiments, the exposed portions of the liner 73 can be removed by an anisotropic dry etching process. For example, the etching process may include a dry etch process using reaction gas(es) that selectively etch the material of the liner 73 at a faster rate than the materials of the dielectric layer 74, the gate spacers 92A and 92B, and the dummy gates 84. In other embodiments, a selective wet etching process may be used to remove the exposed portions of the liner 73. During the removal, the dielectric layer 74 may be used as an etch stop layers when the liner 73 is etched.

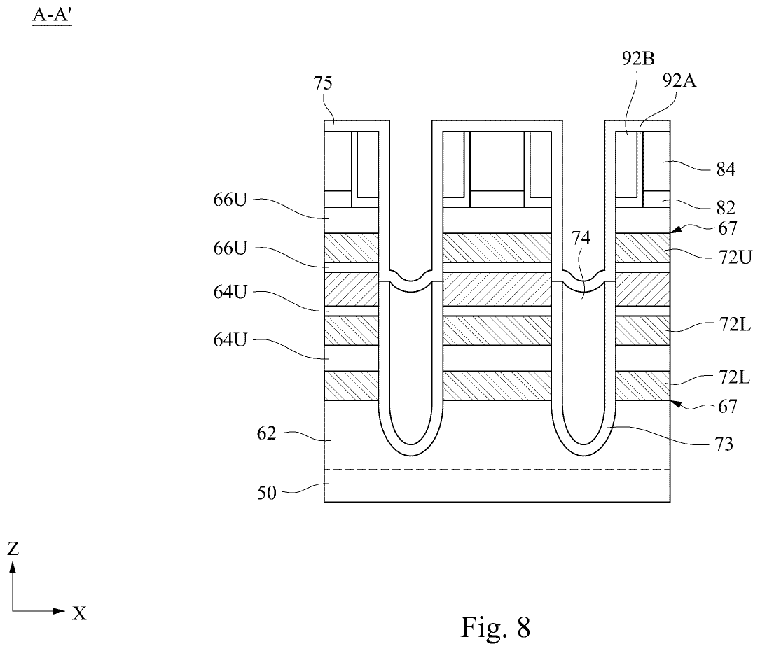

Reference is made to FIG. 8. A hard mask layer 75 can be conformally formed over the structure shown in FIG. 7. The hard mask layer 75 can be formed over sidewalls of the upper dummy regions 72U, the upper semiconductor nanostructures 66U, the gate spacers 92B, and over top surfaces of the etched liner 73 and the dielectric layer 74. The hard mask layer 75 may be formed of one or more dielectric material(s). FIG. 8 shows a hard mask layer 75 formed of a single layer of dielectric material, but in other embodiments the hard mask layer 75 may be formed of two or more layers of dielectric materials. Acceptable dielectric materials may include silicon oxide, silicon nitride, silicon oxynitride, silicon oxycarbonitride, or the like, which may be formed by a deposition process such as CVD, ALD, or the like. Other insulation materials formed by any acceptable process may be used.

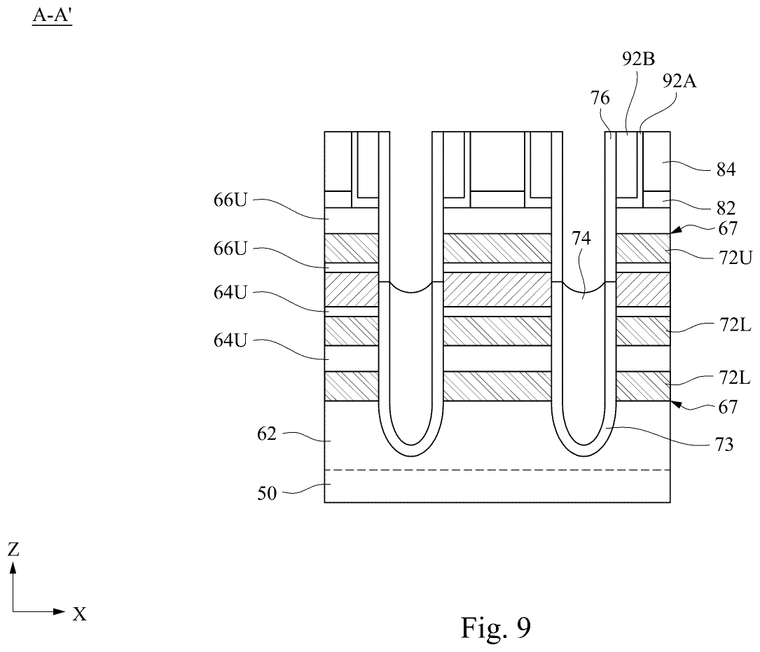

Reference is made to FIG. 9. The hard mask layer 75 can be patterned to form hard mask spacer 76. Any acceptable etching process, such as a dry etch, a wet etch, the like, or a combination thereof, may be performed to pattern the hard mask layer 75. The etching may be anisotropic. The hard mask layer 75, when etched, has portions left on the sidewalls of the upper dummy regions 72U, the upper semiconductor nanostructures 66U, and the gate spacers 92B. After etching, the hard mask spacer 76 may have straight sidewalls or may have curved sidewalls. In some embodiments, the etching stops on the liner 73 and the dielectric layer 74. In other embodiments, the liner 73 and the dielectric layer 74 may also be etched when patterning the hard mask layer 75. For example, the etching may recess portions of the liner 73 and the dielectric layer 74.

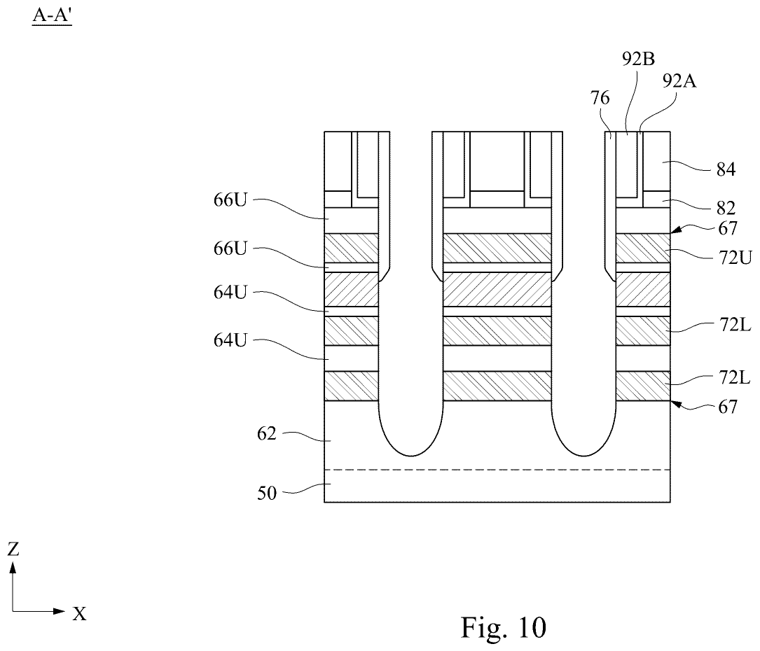

Reference is made to FIG. 10. The remaining liner 73 and dielectric layer 74 can be removed. The remainder of the dielectric layer 74 can be removed, such that the source/drain recesses 96 may reappear. In some embodiments, the remainder of the liner 73 can be also removed along with the dielectric layer 74. Removing the liner 73 and the dielectric layer 74 may include an isotropic wet etching process or the like. The etching process may use etchants which are selective to the materials of the liner 73 and the dielectric layer 74, while the lower dummy regions 72L and the lower semiconductor nanostructures 66L remain relatively unetched. The hard mask spacer 76 can protect the upper dummy regions 72U and the upper semiconductor nanostructures 66U from the etching process. After removing the liner 73 and the dielectric layer 74, the source/drain recess 96 can expose the sidewalls of the lower dummy regions 72U and the lower semiconductor nanostructures 66L.

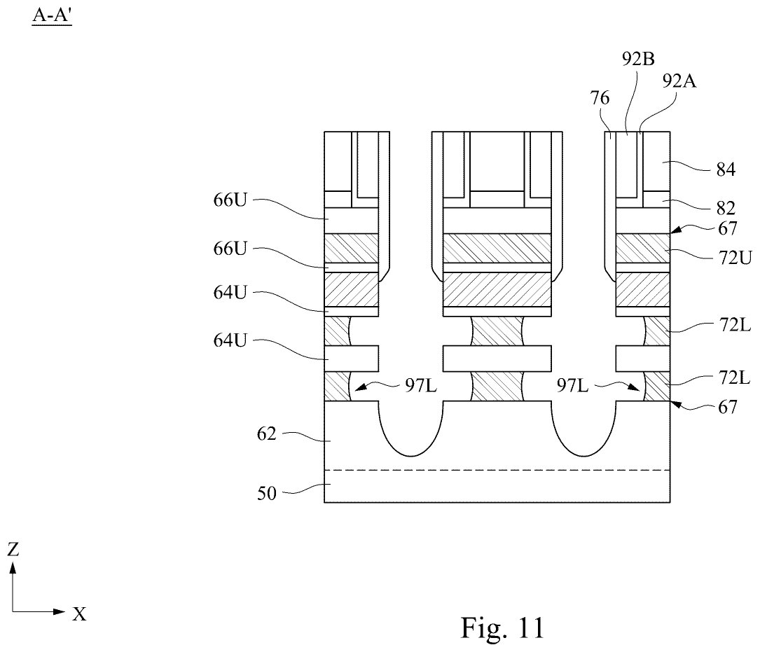

Reference is made to FIG. 11. The lower dummy regions 72L can be etched to form lower sidewall recesses 97L. The etching may be isotropic or anisotropic. For example, the lower dummy regions 72L may be etched using a wet etch process, such as dHF or the like. In some embodiments, the etching is performed such that sidewalls of the lower dummy regions 72L are recessed past sidewalls of the lower semiconductor nanostructures 66L, forming the lower sidewall recesses 97L. Accordingly, the lower dummy regions 72L may have a width that is smaller than widths of the lower and upper semiconductor nanostructures 66L and 66U and the upper dummy regions 72U. In some cases, the lower sidewall recesses 97L may be considered part of the source/drain recesses 96. Although sidewalls of the lower dummy regions 72L within the lower sidewall recesses 97L can be illustrated as being flat, the sidewalls may be concave or convex.

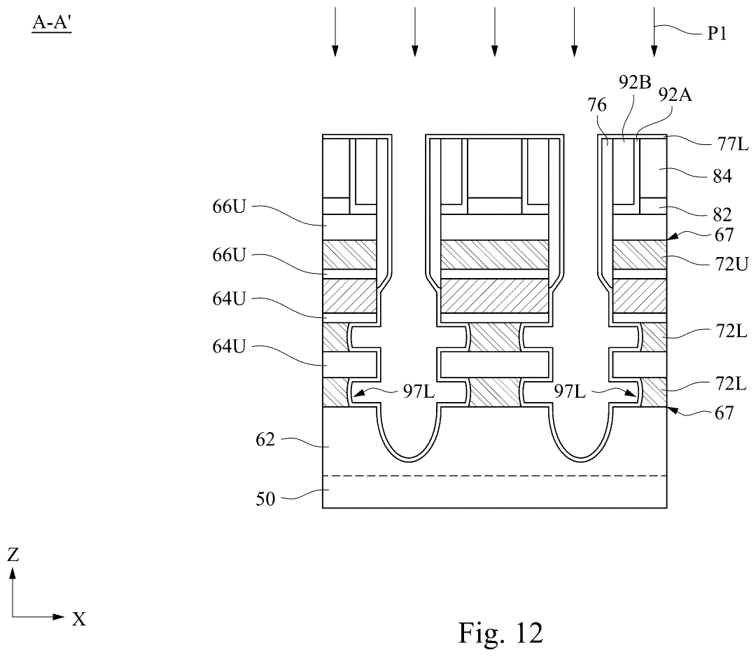

Reference is made to FIG. 12. For an n-type field-effect (NFET) transistor, the well region should be doped with p-type dopants to form PN junctions with channel region and the source/drain region. Similarly, for a p-type FET (or PFET), the well region should be doped with n-type dopants. For advanced semiconductor devices, it is desirable to have electrons and holes moving in the channel regions to have high mobility. In order to improve the mobility of electrons and holes, the dopant density of the channel region may need to be maintained low. In some embodiments, the mobility of electrons and holes may increase with decrease in dopant density. In order to form PN junctions with source regions and drain regions for FETs, the well regions may need to have sufficient amount (or concentration) of dopants higher than the channel region. In some embodiments, well doping can be achieved by implant of dopants.

A first conductivity type dopant layer 77L can be deposited over the structure shown in FIG. 12. The first conductivity type dopant layer 77L can include first conductivity type dopants. The first conductivity type dopant can act as a dopant source and provide dopants for doping a first conductivity type well under an second conductivity type field-effect transistor has an opposite conductivity type to the first conductivity type. In some embodiments, the first conductivity type dopant concentration can be in a range from about 1E19 atoms/cm³ to about 5E20 atoms/cm³.

In some embodiments, the first conductivity type dopant layer 77L can be a p-type dopant layer including p-type dopants, such as boron (B), etc. By way of example but not limiting the present disclosure, the first conductivity type dopant layer 77L can be made of boron-doped silicon glass (BSG, or boron-doped silicon oxide). In some embodiments, the first conductivity type dopant layer 77L can be an n-type dopant layer including n-type dopants, such as phosphorus (P), arsenic (As), etc. In some embodiments, the first conductivity type dopant layer 77L can be made of a dielectric film. By way of example but not limiting the present disclosure, the n-type dopant layer 29 can be made of phosphorus-doped silicon glass (PSG). In some embodiments, the first conductivity type dopant layer 77L can be deposited by a chemical vapor deposition (CVD) process, a plasma-enhanced CVD (PECVD) process, or an atomic layer deposition (ALD) process, in some embodiments. Other applicable processes may also be used.

Afterwards, a dopant diffusion process P1 can be performed. The dopant diffusion process P1 can diffuse the first conductivity type dopants in the first conductivity type dopant layer 77L into the lower semiconductor nanostructures 66L, such that the concentration of first conductivity type wells in the lower semiconductor nanostructures 66L can be in a range from, such as about 1E18 atoms/cm³ to about 6E18 atoms/cm³. The dopant diffusion process P1 could be a rapid thermal annealing (RTA) process or other applicable processes, such as a laser anneal process, a flash process, or a microwave annealing (MWA) process. The dopant diffusion process P1 can effectively spreads dopants evenly throughout the semiconductor material, which in turn evenly adjusts the electrical properties throughout the material without leaving uneven concentrations or gaps. Therefore, in some embodiments, there's no need for the proximity push or convex process, which is used to even out dopant distribution.

By way of example but not limiting the present disclosure, if an RTA process is used, the temperature can be in a range from about 900 to 1000° C. In some embodiments, the duration of the RTA process can by in a range from about 1 to about 10 seconds. In some embodiments, the laser anneal temperature can be greater than about 1000° C. with a duration in a range from about 200 to 400μs. In some embodiments, the flash anneal temperature can be also greater than about 1100° C. for a duration in a range from about 0.2 to 3 ms. In some embodiments, the MWA may also be used for dopant diffusion process P1. The MWA process would rely on atomic polarization and interfacial polarization of dopants diffused into the lower semiconductor nanostructures 66L. The atomic polarization and interfacial polarization would increase the temperatures of the lower semiconductor nanostructures 66L and the first conductivity type dopant layer 77L to be higher than the surrounding structures and materials. In some embodiments, the frequency of the microwave is in a range from about 2 to 10 GHz. In some embodiments, the frequency of the microwave is in a range from about 5 to 6 GHz. In some embodiments, the power of the MWA proves is in a range from about 3000 to 9000 watts. In some embodiments, the temperature of the substrate 50 is in a range from about 400 to 600° C. In some embodiments, the process duration of MWA can be in a range from about 100 to 1200 seconds.

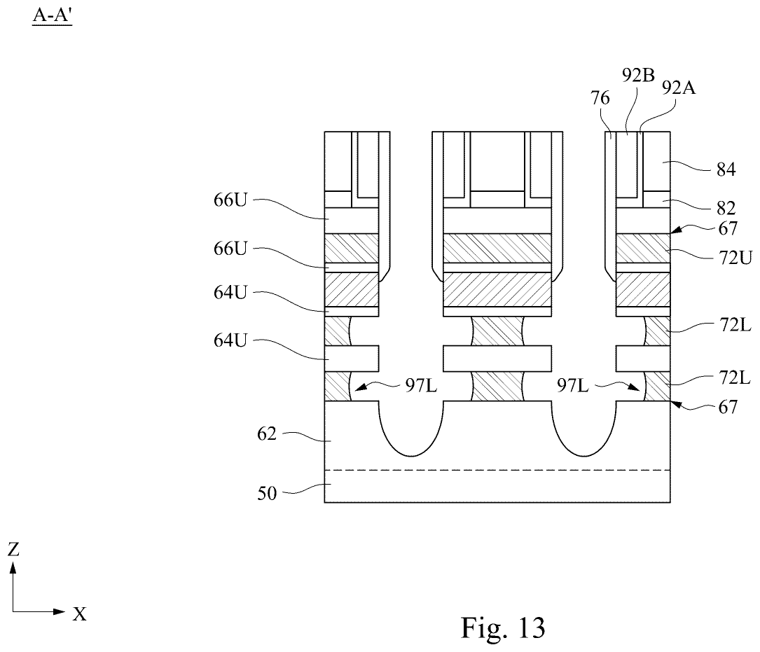

Reference is made to FIG. 13. The first conductivity type dopant layer 77L can be removed by one or more etching processes. The one or more etching processes used to remove the first conductivity type dopant layer 77L may include one or more wet processes, one or more dry process(es), or a combination of both wet and dry processes.

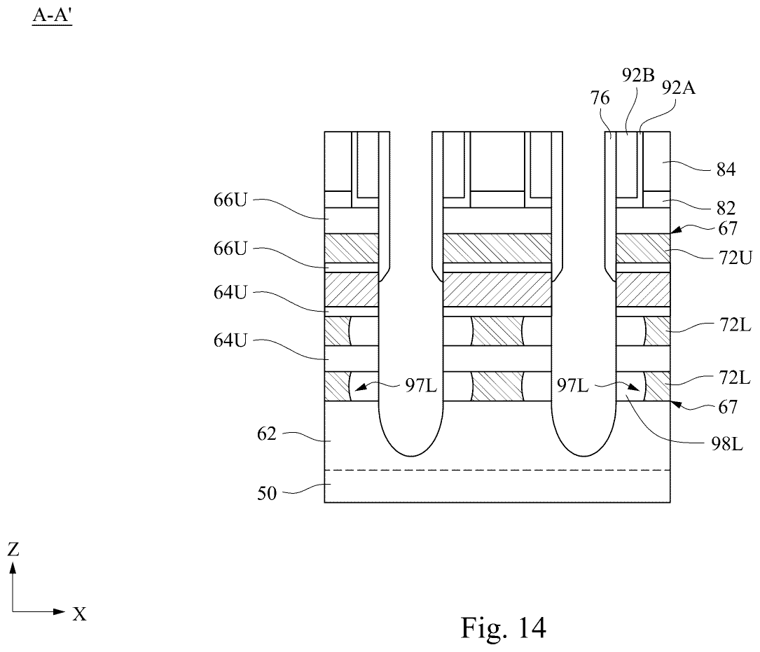

Reference is made to FIG. 14. Lower inner spacers 98L can be formed in the lower sidewall recesses 97L. In other words, the lower inner spacers 98L can be formed on the sidewalls of the lower dummy regions 72L. As will be subsequently described in greater detail, lower source/drain regions can be subsequently formed in the source/drain recesses 96, and the lower dummy regions 72L are subsequently replaced with corresponding lower gate structures. Further, the lower inner spacers 98 may be used to prevent damage to the subsequently formed lower source/drain regions by subsequent etch processes.

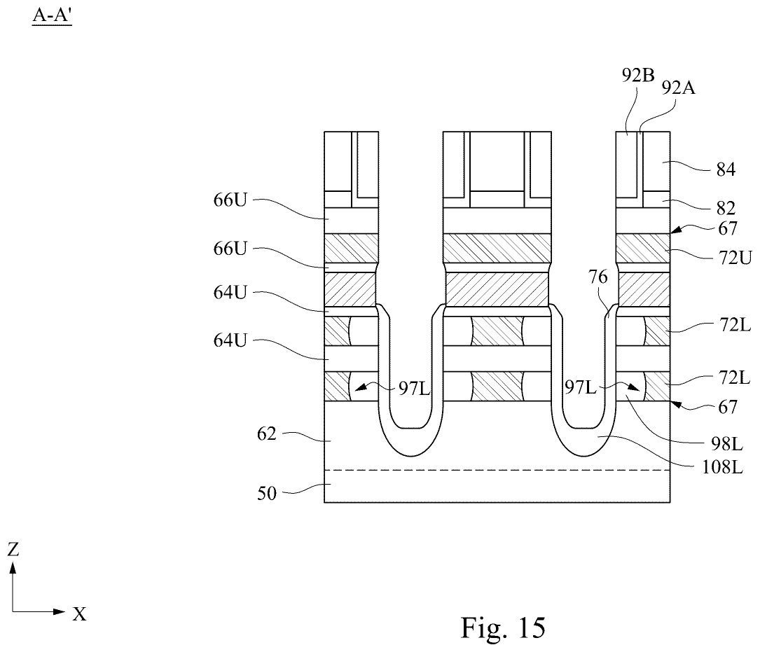

In some embodiments, the lower inner spacers 98L can be formed by conformally depositing a semiconductor material in the source/drain recesses 96 and in the lower sidewall recesses 97L and subsequently etching the semiconductor material. The semiconductor material of the lower inner spacers 98L can allow the lower inner spacers 98L to act as seeding layers for epitaxial growth of the lower epitaxial source/drain regions 108L (see FIG. 15). The quality of the lower epitaxial source/drain regions 108L can be enhanced when the underlying lower inner spacers 98L are of a similar semiconductor material, promoting lattice-matching conditions that are conducive to high-quality crystalline growth. Together with the lower semiconductor nanostructures 66L, the lower inner spacers 98L can form a continuous seeding sidewall, which in turn provides a uniform template over which the epitaxial growth of the lower epitaxial source/drain regions 108L can occur. The homogeneity of this surface can maintain the crystalline integrity of the lower epitaxial source/drain regions 108L. In some embodiments, discontinuities in the seeding layer may lead to defects in the lower epitaxial source/drain regions 108L, which can adversely affect the device's performance.

In some embodiments, the semiconductor material can be selected from the candidate of silicon; germanium; a compound semiconductor including silicon carbide, gallium arsenide, gallium phosphide, indium phosphide, indium arsenide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. The semiconductor material may be grown by a process such as vapor phase epitaxy (VPE) or molecular beam epitaxy (MBE), deposited by a process such as chemical vapor deposition (CVD) or atomic layer deposition (ALD), or the like. The etching of the insulating material may be anisotropic. For example, the etch process may be a dry etch such as a RIE, a NBE, or the like. After performing the etching of the semiconductor material, the remaining portions of the semiconductor material within the lower sidewall recesses 97L form the lower inner spacers 98L. The lower inner spacer 98L may have a thickness that is smaller than, about the same as, or greater than a thickness of an adjacent lower dummy regions 72L.

Although outer sidewalls of the lower inner spacers 98L can be illustrated as being flush (e.g. approximately coplanar) with sidewalls of the lower semiconductor nanostructures 66L, the outer sidewalls of the lower inner spacers 98L may extend beyond or be recessed from sidewalls of the lower semiconductor nanostructures 66L. In other words, the lower inner spacers 98L may partially fill, completely fill, or overfill the lower sidewall recesses 97L. Moreover, although the sidewalls of the lower inner spacers 98L are illustrated as being flat in FIG. 14, the sidewalls of the lower inner spacers 98L may be concave or convex. In some embodiments, sidewalls of the lower dummy regions 72L can be concave, outer sidewalls of the lower inner spacers 98L can be concave, and the lower inner spacers 98L can be recessed from sidewalls of the lower semiconductor nanostructures 66L. In some embodiments, sidewalls of the lower dummy regions 72L can be concave, outer sidewalls of the lower inner spacers 98L can be flat, and outer sidewalls of the lower inner spacers 98L can be flush with sidewalls of the lower semiconductor nanostructures 66L. Other configurations or sidewall profiles are also possible.

In some embodiments, the lower inner spacers 98L, which are composed of a semiconductor material, can be selectively removed (see FIG. 24), resulting in cavities or air gaps where the spacers once existed, termed lower air inner spacers 98L′ (see FIG. 24). These air gaps can reduce parasitic capacitance, thereby enhancing the electrical performance of the device by reducing unwanted charge accumulation and signal delay.

Reference is made to FIG. 15. Lower epitaxial source/drain regions 108L can be formed in the lower portions of the source/drain recesses 94. Each stack of the lower semiconductor nanostructures 66L can be disposed between respective neighboring pairs of the lower epitaxial source/drain regions 108L. Specifically, the dummy spacers 96 mask the upper semiconductor nanostructures 66U, so that the lower epitaxial source/drain regions 108L are formed on the lower semiconductor nanostructures 66L and are not formed on the upper semiconductor nanostructures 66U. The lower epitaxial source/drain regions 108L can be epitaxially grown laterally from exposed sidewalls of the lower semiconductor nanostructures 66L and may merge along the sidewalls of the lower inner spacers and may merge along the sidewalls of the lower inner spacers 98L. On the other hand, the lower epitaxial source/drain regions 108L can be in contact with the lower semiconductor nanostructures 66L and the lower inner spacers 98L and are not in contact with the upper semiconductor nanostructures 66U.

The lower epitaxial source/drain regions 108L can line the lower portions of the source/drain recesses 94, without filling the lower portions of the source/drain recesses 94. Specifically, the growth of the lower epitaxial source/drain regions 108L can be stopped before adjoining growth of the lower epitaxial source/drain regions 108L merges together in the source/drain recesses 94. Thus, the lower epitaxial source/drain regions 108L in a same source/drain recess 94 can have a U-shaped cross-sectional profile. In some embodiments, the thin epitaxial sidewall growth on the lower epitaxial source/drain region 108L can help improve the control over the thickness thereof, allowing for more precise control over the height of the epitaxial source/drain region 108L. Additionally, the thin epitaxial sidewall growth can provide flexibility in the design of the device by allowing for thinner layers, which can save space and enable the stacking of more layers within the same vertical space. In some embodiments, timed growth processes may be used to stop the growth of the lower epitaxial source/drain regions 108L after the lower epitaxial source/drain regions 108L have grown a desired distance from the sidewalls of the lower semiconductor nanostructures 66L. In some embodiments, as the lower epitaxial source/drain regions 108L grow in the source/drain recesses 94, facets may form.

The lower epitaxial source/drain regions 108L may be implanted with dopants to form source/drain regions, followed by an anneal. When the lower epitaxial source/drain regions 108L line the lower portions of the source/drain recesses 94, they can be doped with a large impurity concentration so that they have a sufficient quantity of carriers for the lower nanostructure-FETs to operate. The source/drain regions may have an impurity concentration in the range of 1E21 atoms/cm³ and 1E22 atoms/cm³ when the lower epitaxial source/drain regions 108L have a thickness in the range of about 1 to 5 nm. The n-type and/or p-type impurities for source/drain regions may be any of the impurities previously discussed. In some embodiments, the lower epitaxial source/drain regions 108L can be in situ doped during growth.

The lower epitaxial source/drain regions 108L have a conductivity type that is suitable for the device type of the lower nanostructure-FETs. In some embodiments, the lower epitaxial source/drain regions 108L can exert stress in the respective channel regions of the lower semiconductor nanostructures 66L, thereby improving performance. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, silicon carbide, phosphorous-doped silicon, silicon phosphide, silicon arsenide, antimony-doped silicon, combinations thereof, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, gallium-doped silicon-germanium, boron-doped silicon, germanium, germanium tin, combinations thereof, or the like.

In some embodiments, the lower epitaxial source/drain regions 108L may comprise one or more semiconductor layers. For example, the lower epitaxial source/drain regions 108L may comprise a first semiconductor layer, a second semiconductor layer, and a third semiconductor layer. Any number of semiconductor layers may be used for the lower epitaxial source/drain regions 108L. Each of the first semiconductor layer, the second semiconductor layer, and the third semiconductor layer may be formed of different semiconductor materials and may be doped to different dopant concentrations. In some embodiments, the first semiconductor layer may have a dopant concentration less than the second semiconductor layer and greater than the third semiconductor layer. In embodiments in which the lower epitaxial source/drain regions 108L comprise three semiconductor layers, the first semiconductor layer may be grown from semiconductor features (e.g., the lower semiconductor nanostructures 66L), the second semiconductor layer may be grown on the first semiconductor layer, and the third semiconductor layer may be grown on the second semiconductor layer.

Subsequently, the hard mask spacer 76 can be removed by any acceptable etching process, such as a dry etch, a wet etch, the like, or a combination thereof. In some embodiments, the etching may be anisotropic. In some embodiments, the etching may be isotropic.

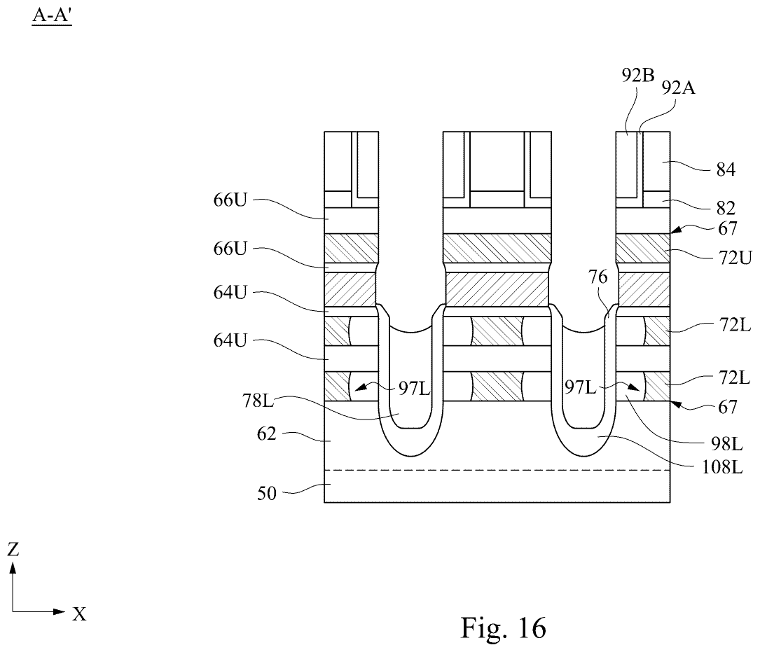

Reference is made to FIG. 16. To enhance transistor performance further, strain may be introduced in the transistor channel for improving carrier mobilities. A lower stress material 78L having an inherent stress can be formed on the lower epitaxial source/drain regions 108L. Specifically, the lower stress layer 78L can be deposited over the structure shown in FIG. 15 and in the source/drain recesses 96. The lower stress layer 78L may be formed by a deposition process such as CVD, ALD, or the like. The lower stress layer 78L, situated between the lower epitaxial source/drain regions 108L can compensate for stress loss in the n-type and p-type channel regions (e.g., lower semiconductor nanostructures 66L) that can occur when the lower epitaxial source/drain regions 108L do not merge. By filling the gaps between the lower epitaxial source/drain regions 108L, the lower stress layer 78L can help maintain the mechanical stress levels within the channel regions. For p-type channels, the lower stress layer 78L can provide compressive stress, and for n-type channels, the lower stress layer 78L can provide tensile stress.

In some embodiment, material of the lower stress slayer 78L can be selected to have an inherent stress that exerts a compressive stress to the lower semiconductor nanostructures 66L. Thus, the lower stress layer 78L may have an inherent tensile stress (e.g. tensile stress layer). In some embodiments, the lower stress slayer 78L may include silicon, SiGe, SiC, the like, or combinations thereof. In some embodiments, an annealing process may be performed with an environment containing H₂O, O₂, or other oxide-containing gas, such that the annealing process may cause oxidation of the lower stress slayer 78L. The oxidation may increase the size (or volume) of the lower stress slayer 78L. Therefore, the oxidized lower stress slayer 78 may exert a compressive stress to the lower semiconductor nanostructures 66L. For example, in some embodiments where the lower stress slayer 78L includes Si, the annealing process is performed such that the lower stress slayer 78L is converted to SiOCN.

In some embodiment, the lower stress layer 78L can be implanted with ions to alter the characteristics of the lower stress layer 78L to form implanted the lower stress layer 78L. It is thought that the ion implant can relax the intrinsic stress in the lower stress layer 78L. Examples of ions-containing implants that can be used are Ge, Si, P, B, the like, or combinations thereof. Relaxes means less or lower stress. Any ion that can reduce the stress of the stress film can be used. By way of example but not limiting the present disclosure, the ion implant can implant boron-containing ions into the lower stress layer 78L. The ion implant process may comprise, for example, implanting B, BF₂ or B₂F₅ ions and at a dose between about 1E14 and 5E15 ions per square centimeter at an energy between about 1 and 25 KeV. In some embodiment, the ion implantation process may be a beam-line ion implantation process, a plasma immersion ion implantation (PIII), the like, or combinations thereof. Subsequently, an annealing process can be conducted, aimed at maintaining the relaxation of the lower stress layer 78L. In some embodiments, the anneal process may be performed at a temperature of, for example, between about 750 and 1100° C. for a time between about, for example, 1 second and 5 minutes. It is noted that other anneals would be effective as long as they meet these minimum requirements or have such sufficient thermal cycle. In some embodiment, this annealing process can be not mandatory, and subsequent processing stages may involve high-temperature annealing steps. For example, the lower stress layer 78L may be annealed during a subsequent anneal, such as a S/D anneal, silicide anneal, any anneal during subsequent device processing, etc.

In some embodiment, material of the lower stress layer 78L can be selected to an inherent stress that exerts a tensile stress to the lower semiconductor nanostructures 66L. Thus, the lower stress layer 78L may have an inherent compressive stress (e.g. compressive stress layer). In some embodiment, the lower stress layer 78L can include a dielectric material that is selected to have hydrogen terminals. The hydrogen terminals may result in nano gas bubbles in the lower stress layer 78L, and the nano gas bubbles may shrink when temperature degrades, thereby result in the tensile stress in subsequent annealing process. In some embodiments, the formation of the stress material may include using a SiH₂Cl₂ precursor to react with a NH₃ plasma, for example, at a temperature higher than 500° C., thereby forming SiNH₂ or SiNH as the resulted lower stress layer 78L. Therefore, the resulted lower stress layer 78L (e.g., SiNH₂ or SiNH) has hydrogen terminal therein. In some embodiments, materials of the lower stress layer 78L may include the group of NH, NH₂, CH, CH₃, or the like. For example, the lower stress layer 78L can include silicon nitride (including NH, NH₂), SiC, SiCN, SiCON (including CHₓ), CHₓ, the like, or the combination thereof. Quality and quantity of the hydrogen terminals can be examined by suitable analysis method, such as Fourier-transform infrared (FT-IR) spectrophotometer.

In some embodiments, the lower stress layer 78L may include material that can crystalize, such as metal-containing compounds. In some embodiments, the lower stress layer 78L may crystallized by the subsequent annealing process, thereby providing tensile stress.

In some embodiment, the lower stress layer 78L can be implanted with ions to alter the characteristics of the lower stress layer 78L to form implanted the lower stress layer 78L, thereby providing tensile stress. It is thought that the ion implant can strengthen the intrinsic stress in the lower stress layer 78L. Strengthen means greater or higher stress. Any ion that can increase the stress of the stress film can be used. Subsequently, an annealing process can be conducted, aimed at maintaining the strength of the lower stress layer 78L. In some embodiments, the implantation process and the anneal process can be similar to the implantation process and the anneal process for forming the lower stress layer 78L having inherent tensile stress (e.g. tensile stress layer).

Subsequently, an etch back process can be performed on the lower stress layer 78L to scale down the lower stress layer 78L. In some embodiments, the etch back process may include a bias plasma etching step. In some embodiments, the bias plasma etching step may use a gas mixture of Cl₂, O₂, BCl₃, and Ar with a bias in a range from about 25V to about 1200V. The bias plasma etching step may be performed to remove portions of the lower stress layer 78L, such that portions of the source/drain recesses 96 may reappear with shallower depth.

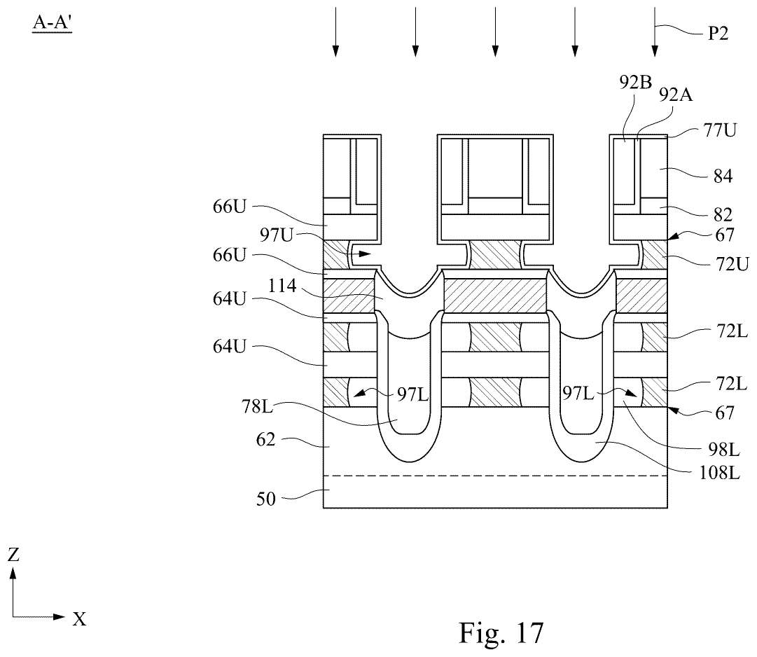

Reference is made to FIG. 17. An isolation dielectric 114 can be formed on the lower epitaxial source/drain regions 108L and the lower stress layer 78L. The isolation dielectric 114 act as isolation feature between the lower epitaxial source/drain regions 108L and subsequently formed upper epitaxial source/drain regions 108U. The isolation dielectric 114 may be formed by conformally forming a dielectric material in the source/drain recesses 94 and subsequently recessing the dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to recess the dielectric material. The etching may be isotropic, such as an etch-back process that removes the dielectric material from the upper portions of the source/drain recesses 94. The dielectric material, when etched, has portions left on the lower stress layer 78L (thus forming the isolation dielectric 114). The isolation dielectric 114 can have a profile characterized by a concave top surface and a convex bottom surface, allowing the bottom surface of the isolation dielectric 114 to be positioned lower than the top of the lower epitaxial source/drain region 108L. The isolation dielectric 114 can extend into the lower epitaxial source/drain region 108L, enabling it to establish contact with the lower stress layer 78L. In some embodiments, the isolation dielectric 114 can have a profile, that can be further accentuated by a narrower width in the lower portion of the isolation dielectric 114 compared to its upper portion. Additionally, the isolation dielectric 114 may exhibit a curved profile or take on a U-shaped cross-sectional profile.

Subsequently, the upper dummy regions 72U can be etched to form upper sidewall recesses 97U. The etching may be isotropic or anisotropic. The etching may be isotropic or anisotropic. For example, the upper dummy regions 72U may be etched using a wet etch process, such as dHF or the like. In some embodiments, the etching is performed such that sidewalls of the upper dummy regions 72U are recessed past sidewalls of the upper semiconductor nanostructures 66U, forming the upper sidewall recesses 97U. Accordingly, the upper dummy regions 72U may have a width that is smaller than widths of the lower and upper semiconductor nanostructures 66L and 66U. In some cases, the upper sidewall recesses 97U may be considered part of the source/drain recesses 96. Although sidewalls of the upper dummy regions 72U within the upper sidewall recesses 97U can be illustrated as being flat, the sidewalls may be concave or convex.

Subsequently, a second conductivity type dopant layer 77U can be deposited over the structure shown in FIG. 17. The second conductivity type dopant layer 77U can include second conductivity type dopants. The second conductivity type dopant can act as a dopant source and provide dopants for doping a second conductivity type well under an first conductivity type field-effect transistor has an opposite conductivity type to the second conductivity type. In some embodiments, the second conductivity type dopant layer 77U can have an opposite conductivity type to the first conductivity type dopant layer 77L. In some embodiments, the second conductivity type dopant layer 77U can have a same conductivity type as the first conductivity type dopant layer 77L. In some embodiments, the second conductivity type dopant concentration can be in a range from about 1E19 atoms/cm³ to about 5E20 atoms/cm³.

In some embodiments, the second conductivity type dopant layer 77U can be a p-type dopant layer including p-type dopants, such as boron (B), etc. By way of example but not limiting the present disclosure, the second conductivity type dopant layer 77U can be made of boron-doped silicon glass (BSG, or boron-doped silicon oxide). In some embodiments, the second conductivity type dopant layer 77U can be an n-type dopant layer including n-type dopants, such as phosphorus (P), arsenic (As), etc. In some embodiments, the second conductivity type dopant layer 77U can be made of a dielectric film. By way of example but not limiting the present disclosure, the n-type dopant layer 29 can be made of phosphorus-doped silicon glass (PSG). In some embodiments, the second conductivity type dopant layer 77U can be deposited by a chemical vapor deposition (CVD) process, a plasma-enhanced CVD (PECVD) process, or an atomic layer deposition (ALD) process, in some embodiments. Other applicable processes may also be used.

Afterwards, a dopant diffusion process P2 can be performed. The dopant diffusion process P2 can diffuse the first conductivity type dopants in the first conductivity type dopant layer 77L into the upper semiconductor nanostructures 66U, such that the concentration of second conductivity type wells in the upper semiconductor nanostructures 66U can be in a range from, such as about 1E18 atoms/cm³ to about 6E18 atoms/cm³. In some embodiments, the dopant diffusion process P2 can be similar to the dopant diffusion process P1 as shown in FIG. 12.

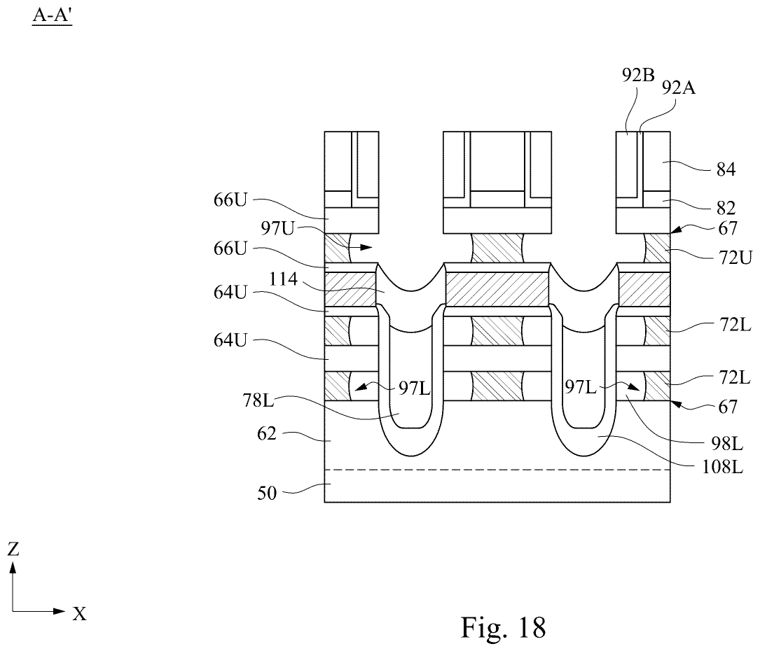

Reference is made to FIG. 18. The second conductivity type dopant layer 77U can be removed by one or more etching processes. The one or more etching processes used to remove the first conductivity type dopant layer 77U may include one or more wet processes, one or more dry process(es), or a combination of both wet and dry processes.

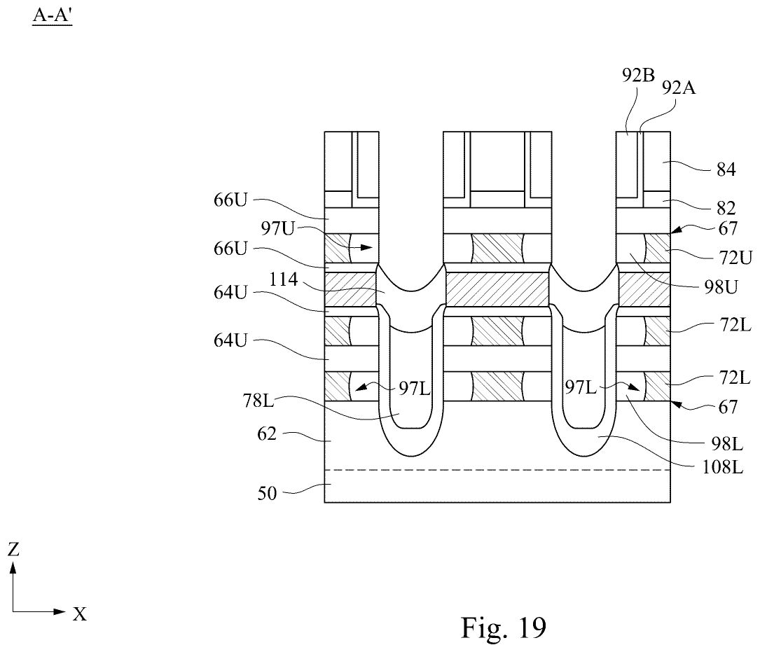

Reference is made to FIG. 19. Upper inner spacers 98U can be formed in the upper sidewall recesses 97U. In other words, the upper inner spacers 98U can be formed on the sidewalls of the upper dummy regions 72U. As will be subsequently described in greater detail, upper source/drain regions are subsequently formed in the source/drain recesses 96, and the upper dummy regions 72U are subsequently replaced with corresponding upper gate structures. Further, the lower inner spacers 98 may be used to prevent damage to the subsequently formed upper source/drain regions by subsequent etch processes.

In some embodiments, the upper inner spacers 98U can be substantially similar to that in FIG. 14 in terms of their material and manufacturing methods. After performing the etching of the semiconductor material, the remaining portions of the semiconductor material within the upper sidewall recesses 97U form the upper inner spacers 98U. The lower inner spacer 98L may have a thickness that is smaller than, about the same as, or greater than a thickness of an adjacent upper dummy regions 72U. Although outer sidewalls of the upper inner spacers 98U can be illustrated as being flush (e.g. approximately coplanar) with sidewalls of the upper semiconductor nanostructures 66U, the outer sidewalls of the upper inner spacers 98U may extend beyond or be recessed from sidewalls of the upper semiconductor nanostructures 66U. In other words, the upper inner spacers 98U may partially fill, completely fill, or overfill the upper sidewall recesses 97U. Moreover, although the sidewalls of the upper inner spacers 98U are illustrated as being flat in FIG. 19, the sidewalls of the upper inner spacers 98U may be concave or convex. In some embodiments, sidewalls of the upper dummy regions 72U can be concave, outer sidewalls of the upper inner spacers 98U can be concave, and the upper inner spacers 98U can be recessed from sidewalls of the upper semiconductor nanostructures 66U. In some embodiments, sidewalls of the upper dummy regions 72U can be concave, outer sidewalls of the upper inner spacers 98U can be flat, and outer sidewalls of the upper inner spacers 98U can be flush with sidewalls of the upper semiconductor nanostructures 66U. Other configurations or sidewall profiles are also possible.

In some embodiments, the upper inner spacers 98U, which are composed of a semiconductor material, can be selectively removed (see FIG. 24), resulting in cavities or air gaps where the spacers once existed, termed lower air inner spacers 98U′ (see FIG. 24). These air gaps can reduce parasitic capacitance, thereby enhancing the electrical performance of the device by reducing unwanted charge accumulation and signal delay.

Reference is made to FIG. 20. Upper epitaxial source/drain regions 108U can be formed in the upper portions of the source/drain recesses 94. Each stack of the upper semiconductor nanostructures 66U can be disposed between respective neighboring pairs of the upper epitaxial source/drain regions 108U. Specifically, the isolation dielectric 114 can mask the lower semiconductor nanostructures 66L, so that the upper epitaxial source/drain regions 108U are formed on the upper semiconductor nanostructures 66U and are not formed on the lower semiconductor nanostructures 66L. The upper epitaxial source/drain regions 108U can be epitaxially grown laterally from exposed sidewalls of the upper semiconductor nanostructures 66U and may merge along the sidewalls of the lower inner spacers and may merge along the sidewalls of the lower upper spacers 98U. On the other hand, the upper epitaxial source/drain regions 108U can be in contact with the upper semiconductor nanostructures 66U and the upper inner spacers 98U and are not in contact with the upper semiconductor nanostructures 66U.

The upper epitaxial source/drain regions 108U can line the upper portions of the source/drain recesses 94, without filling the upper portions of the source/drain recesses 94. Specifically, the growth of the upper epitaxial source/drain regions 108U can be stopped before adjoining growth of the upper epitaxial source/drain regions 108U merges together in the source/drain recesses 94. Thus, the upper epitaxial source/drain regions 108U in the same source/drain recess 94 are completely separated from one another, and the isolation dielectric 114 remains exposed by the source/drain recesses 94 after the upper epitaxial source/drain regions 108U are formed. Timed growth processes may be used to stop the growth of the upper epitaxial source/drain regions 108U after the upper epitaxial source/drain regions 108U have grown a desired distance from the sidewalls of the upper semiconductor nanostructures 66U. In some embodiments, as the upper epitaxial source/drain regions 108U grow in the source/drain recesses 94, facets may form.

In some embodiments, the upper epitaxial source/drain regions 108U can be substantially similar to the lower epitaxial source/drain regions 108L illustrated in FIG. 15 in terms of their material and manufacturing methods. In some embodiments, the upper epitaxial source/drain regions 108U can have an opposite conductivity type to the lower epitaxial source/drain regions 108L. By way of example but not limiting the present disclosure, the upper epitaxial source/drain region 108U can be an n-type source/drain region, and the lower epitaxial source/drain regions 108L can a p-type source/drain region. In some embodiments, the upper epitaxial source/drain region 108U can be a p-type source/drain region, and the lower epitaxial source/drain regions 108L can an n-type source/drain region. In some embodiments, the upper epitaxial source/drain regions 108U can have a same conductivity type as the lower epitaxial source/drain regions 108L.

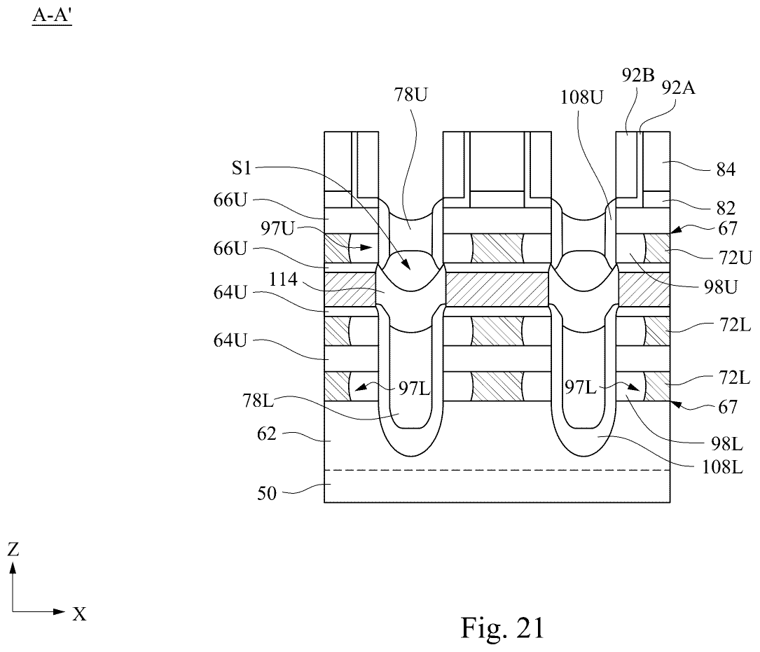

Reference is made to FIG. 21. To enhance transistor performance further, strain may be introduced in the transistor channel for improving carrier mobilities. An upper stress material 78U having an inherent stress can be formed on the source/drain regions 108L. Specifically, the lower stress layer 78L can be deposited over the structure shown in FIG. 20 and in the source/drain recesses 96. In some embodiments, the upper stress material 78U can be substantially similar to the lower stress material 78L illustrated in FIG. 16 in terms of their material and manufacturing methods. In some embodiments, the upper stress material 78U may have an opposite stress characteristic to the lower stress material 78L. By way of example but not limiting the present disclosure, the upper stress material 78U can exert a tensile stress to the upper semiconductor nanostructures 66U, and the lower stress material 78L can exert a compressive stress to the lower semiconductor nanostructures 66L. In some embodiments, the upper stress material 78U can exert a compressive stress to the upper semiconductor nanostructures 66U, and the lower stress material 78L can exert a tensile stress to the lower semiconductor nanostructures 66L. In some embodiments, the upper stress material 78U may have a same stress characteristic opposite as the lower stress material 78L. In some embodiments, a space S1 can be formed between the isolation dielectric 114 and the upper stress material 78U, such as due to the compact nature of the source/drain recesses 96, leaving limited room for, such as material expansion and stress accommodation. From a cross-sectional view as shown in FIG. 21, the space S1 can be defined by a concave top surface of the isolation dielectric 114 and a convex bottom surface of the upper stress material 78U.

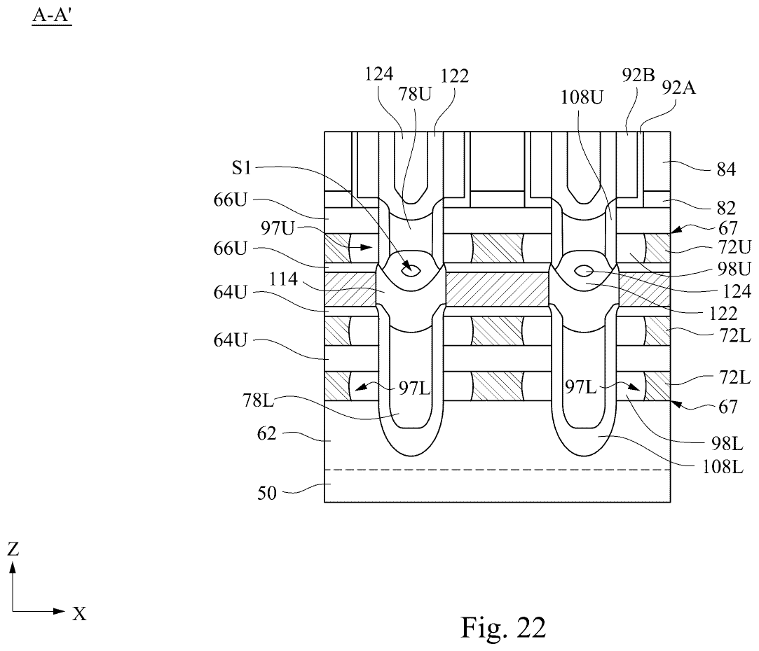

Reference is made to FIG. 22. An inter-layer dielectric (ILD) layer 124 can be deposited over the upper stress material 78U, the upper epitaxial source/drain regions 108U, the isolation dielectric 114, the gate spacers 92A and 92B, and the dummy gates 84. The ILD layer 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

In some embodiments, a contact etch-stop layer (CESL) 122 can be formed between the ILD layer 124 and the upper stress material 78U, the upper epitaxial source/drain regions 108U, the isolation dielectric 114, the gate spacers 92A and 92B, and the dummy gates 84. The CESL 122 may be formed of a dielectric material having a high etching selectivity to the dielectric material of the ILD layer 124, such as silicon nitride, silicon oxide, silicon oxynitride, or the like, which may be formed by any suitable deposition process, such as CVD, ALD, or the like.

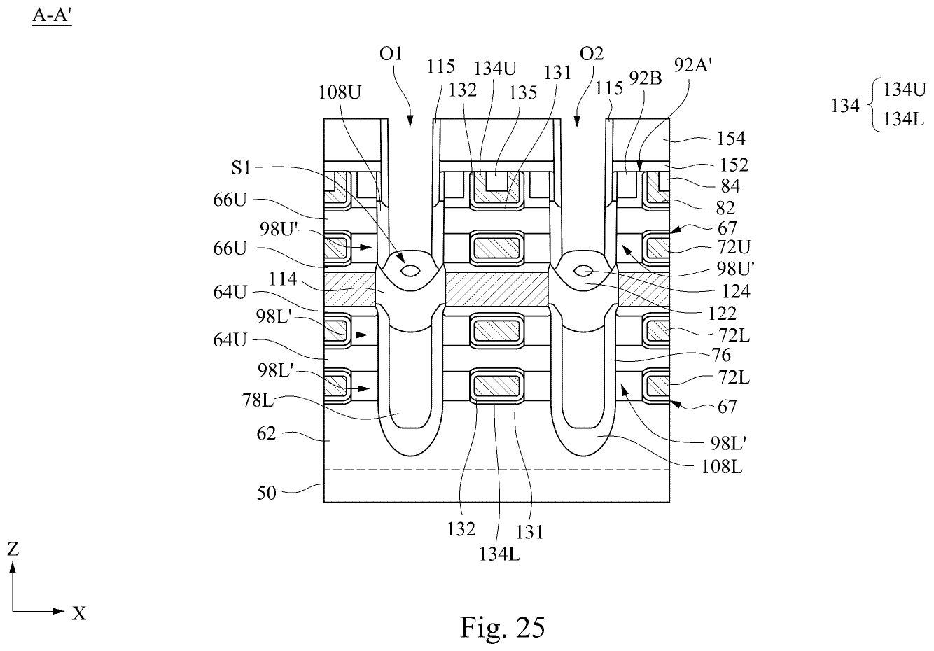

During the formation of the upper stress material 78U, due to the compact spacing between the upper epitaxial source/drain regions 108U, the upper stress material 78U may tend to merge between the upper epitaxial source/drain regions 108U. On the other hand, the upper stress material 78U might not merge outside the spaces between the upper epitaxial source/drain regions 108U, potentially forming gaps in those outer areas. Then, during the deposition of the CESL 122 and ILD layer 124, the upper stress material 78U can fill downwards into the space S1, utilizing the formed gaps as pathways to extend the material coverage. As the CESL 122 and the ILD layer 124 are deposited, they can fill in and conform to the contours of space S1. The space S1 can serve as a mold that can guide the deposition of the CESL 122 and the ILD layer 124, ensuring they encapsulate and conform to the surrounding structures. The CESL 122 and the ILD layer 124 are subsequently formed, and thus from a cross-sectional view, as illustrated in FIG. 22, the CESL 122 not only can cover the upper stress material 78U but also wrap around the ILD layer 124. In some embodiments, the CESL 122 can provide a robust etch stop during subsequent processing steps (see FIG. 25), while the ILD layer 124 serves as an effective insulating material, enhancing the electrical isolation between different device components. In some embodiments, by forming into the space S1, the CESL 122 and the ILD layer 124 can maintain the mechanical stability of the device by filling the space S1 and provide a uniform layer that supports and protects the underlying components.

Subsequently, a removal process can be performed to level the top surfaces of the ILD layer 124 with the top surfaces of the gate spacers 92A and 92B and the dummy gates 84. In some embodiments, a planarization process such as a chemical mechanical polish (CMP), an etch-back process, combinations thereof, or the like may be utilized. The planarization process may also remove portions of the gate spacers 92A and 92B. After the planarization process, top surfaces of the ILD layer 124, the gate spacers 92A and 92B, and the dummy gates 84 can be substantially coplanar (within process variations). Accordingly, the top surfaces of the dummy gates 84 and the gate spacers 92A and 92B can be exposed through the ILD layer 124.

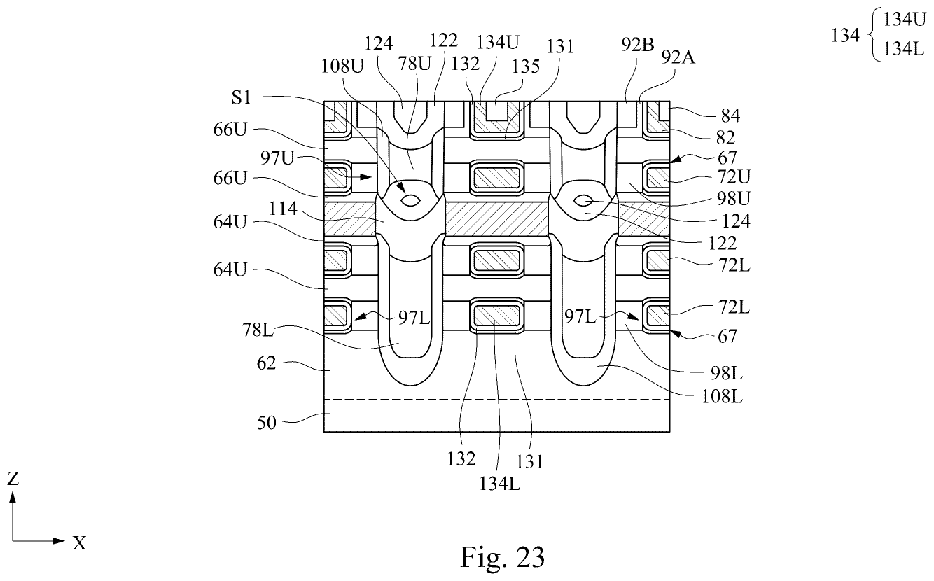

Reference is made to FIG. 23. The dummy gates 84 can be removed in one or more etching steps, so that recesses 126 can be formed between the gate spacers 92A and 92B. Portions of the dummy dielectrics 82 in the recesses 126 can be also removed. In some embodiments, the dummy gates 84 and the dummy dielectrics 82 can be removed by an anisotropic dry etch process. For example, the etching process may include a dry etch process using reaction gas(es) that selectively etch the material of the dummy gates 84 at a faster rate than the materials of the ILD layer 124, the lower and upper inner spacers 98L and 98U, the gate spacers 92A and 92B, and the dielectric layers 70. Each recess 126 exposes and/or overlies portions of the lower and upper semiconductor nanostructures 66L and 66U which act as the channel regions in the resulting devices. The portions of the lower and upper semiconductor nanostructures 66L and 66U which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

Subsequently, the remaining portions of the lower and upper dummy regions 72L and 72U can be then removed to form openings 128 in regions between the lower and upper semiconductor nanostructures 66L and 66U. The remaining portions of the lower and upper dummy regions 72L and 72U can be removed by any acceptable etch process that selectively etches the material of the lower and upper dummy regions 72L and 72U at a faster rate than the materials of the lower and upper semiconductor nanostructures 66L and 66U, the dielectric layers 70, and the lower and upper inner spacers 98L and 98U. Removing the lower and upper dummy regions 72L and 72U may include performing an isotropic etching process such as wet etching or the like using etchants which are selective to the materials of the lower and upper dummy regions 72L and 72U, while the lower and upper semiconductor nanostructures 66L and 66U and the lower and upper inner spacers 98L and 98U remain relatively unetched as compared to the lower and upper dummy regions 72L and 72U. In some embodiments, a trim process can be performed to decrease the thicknesses of the exposed portions of the lower and upper semiconductor nanostructures 66L and 66U and expand the openings 128.

Subsequently, gate dielectrics 132 and gate electrodes 134 (including lower gate electrodes 134L and upper gate electrodes 134U) can be formed for replacement gates. Each respective pair of a gate dielectric 132 and a gate electrode 134 (including an upper gate electrode 134U and/or a lower gate electrode 134L) may be collectively referred to as a “gate structure.” Each gate structure extends along three sides (e.g., a top surface, a sidewall, and a bottom surface) of a channel region of a semiconductor nanostructure 66U/66U. The gate structures may also extend along sidewalls and/or a top surface of a semiconductor fin 62.

The gate dielectrics 132 include one or more gate dielectric layer(s) disposed on the sidewalls and/or the top surfaces of the semiconductor fins 62; on the top surfaces, the sidewalls, and the bottom surfaces of the channel regions of the lower semiconductor nanostructures 66L and the upper semiconductor nanostructures 66U; on the sidewalls of the inner spacers 98L and 98U; and on the sidewalls of the gate spacers 92A. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer. In some embodiments, interfacial layers 131, such as oxide layers (e.g., silicon oxide) can be formed on the sidewalls and/or the top surfaces of the semiconductor fins 62; on the top surfaces, the sidewalls, and the bottom surfaces of the channel regions of the lower semiconductor nanostructures 66L and the upper semiconductor nanostructures 66U.

The lower gate electrodes 134L can include one or more gate electrode layer(s) disposed over the gate dielectrics 132 and around the lower semiconductor nanostructures 66L. The lower gate electrodes 134L can be disposed in the lower portions of the recesses 126 and in the openings 128 between the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. The lower gate electrodes 134L can be formed of material(s) that are suitable for the device type of the lower nanostructure-FETs. For example, the lower gate electrodes 134L may include one or more work function tuning layer(s) formed of work function tuning material(s) that are suitable for the device type of the lower nanostructure-FETs. In some embodiments, the lower gate electrodes 134L include an n-type work function tuning layer, which may be formed of an n-type work function tuning material such as titanium aluminum, titanium aluminum carbide, tantalum aluminum, tantalum carbide, combinations thereof, or the like. In some embodiments, the lower gate electrodes 134L include a p-type work function tuning layer, which may be formed of a p-type work function tuning material such as titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof. Although single-layered gate electrodes are illustrated, the lower gate electrodes 134L may include any number of work function tuning layers, any number of barrier layers, any number of glue layers, and a fill material. In some embodiments, a filling material 135 can be formed over the upper gate electrode 134U.

The upper gate electrodes 134U can include one or more gate electrode layer(s) disposed over the gate dielectrics 132 and around the upper semiconductor nanostructures 66U. The upper gate electrodes 134U can be disposed in the upper portions of the recesses 126 and in the openings 128 between the upper semiconductor nanostructures 66U. The upper gate electrodes 134U/the filling material 135 may be formed of a metal-containing material such as tungsten, titanium, titanium nitride, tantalum, tantalum nitride, tantalum carbide, aluminum, ruthenium, cobalt, combinations thereof, multi-layers thereof, or the like. The upper gate electrodes 134U can be formed of material(s) that are suitable for the device type of the upper nanostructure-FETs. For example, the upper gate electrodes 134U may include one or more work function tuning layer(s) formed of work function tuning material(s) that are suitable for the device type of the upper nanostructure-FETs. In some embodiments, the upper gate electrodes 134U include an n-type work function tuning layer, which may be formed of an n-type work function tuning material such as titanium aluminum, titanium aluminum carbide, tantalum aluminum, tantalum carbide, combinations thereof, or the like. In some embodiments, the upper gate electrodes 134U include a p-type work function tuning layer, which may be formed of a p-type work function tuning material such as titanium nitride, tantalum nitride, combinations thereof, or the like. The work function tuning material(s) of the upper gate electrodes 134U may be different than the work function tuning material(s) of the lower gate electrodes 134L. Additionally or alternatively, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L. Although single-layered gate electrodes are illustrated, the upper gate electrodes 134U may include any number of work function tuning layers, any number of barrier layers, any number of glue layers, and a fill material.

As an example to form the gate structures, one or more gate dielectric layer(s) may be deposited in the recesses 126 and the openings 128. The gate dielectric layer(s) may also be deposited on the top surfaces of the ILD layer 124 and the gate spacers 92A and 92B. Subsequently, one or more lower gate electrode layer(s) may be deposited on the gate dielectric layer(s), and in the remaining portions of the recesses 126 and the openings 128. The lower gate electrode layer(s) may then be recessed. Any acceptable etch process, such as a dry etch, a wet etch, the like, or a combination thereof, may be performed to recess the lower gate electrode layer(s). The etching may be isotropic, such as an etch-back process that removes the lower gate electrode layer(s) from the upper portions of the recesses 126, such that the lower gate electrode layer(s) remain in the openings 128 between the lower semiconductor nanostructures 66L. Subsequently, one or more upper gate electrode layer(s) may be deposited over the lower gate electrode layer(s), and in the remaining portions of the recesses 126 and the openings 128. A removal process is performed to remove the excess portions of the upper gate electrode layer(s), which excess portions are over the top surfaces of the gate spacers 92A and 92B and the ILD layer 124, such that the upper gate electrode layer(s) remain in the openings 128 between the upper semiconductor nanostructures 66U. In some embodiments, a planarization process such as a chemical mechanical polish (CMP), an etch-back process, combinations thereof, or the like may be utilized. The gate dielectric layer(s), after the removal process, have portions remaining in the recesses 126 and the openings 128 (thus forming the gate dielectrics 132). The lower gate electrode layer(s), after the removal process, have portions left in the lower portions of the recesses 126 and in the openings 128 between the lower semiconductor nanostructures 66L (thus forming the lower gate electrodes 134L). The upper gate electrode layer(s), after the removal process, have portions left in the upper portions of the recesses 126 and in the openings 128 between the upper semiconductor nanostructures 66U (thus forming the upper gate electrodes 134U). The dielectric material, after the removal process, has portions left between the lower gate electrodes 134L and the upper gate electrodes 134U (thus forming the isolation layers 136). When a planarization process is utilized, the top surfaces of the gate spacers 92A and 92B, the ILD layer 124, the gate dielectrics 132, and the gate electrodes 134 (e.g., the upper gate electrodes 134U) are coplanar (within process variations).

Reference is made to FIG. 24. The gate spacers 92A can be removed to form air gate spacers 92A′. In some embodiments the removal of the gate spacers 92A, which can be performed using a wet etch. The etchant can be selected so that in the wet etch, the gate spacers 92A can be removed, and the gate structures, the gate spacers 92B, and the ILD layer 124 are not etched. In some embodiments, the wet etch can be performed using a chemical comprising HF and NH₃.

Subsequently, the upper and lower inner spacers 98L and 98U can be removed through the air gate spacers 92A′ to form upper and lower air inner spacers 98L′ and 98U′. The upper and lower inner spacers 98L and 98U can be removed by any acceptable etch process that selectively etches the materials of the upper and lower inner spacers 98L and 98U at a faster rate than the materials of the lower and upper semiconductor nanostructures 66L and 66U, the dielectric layers 70, and the upper and lower epitaxial source/drain regions 108U and 108L. In some embodiments, the etching may be isotropic. For example, when the lower and upper inner spacers 98L and 98U are formed of silicon-germanium and the lower and upper semiconductor nanostructures 66 are formed of silicon, the etch process may be a wet etch using tetramethylammonium hydroxide (TMAH), ammonium hydroxide (NH₄OH), or the like.

The upper and lower air inner spacers 98U′ and 98L′ can reduce parasitic capacitance, thereby enhancing the electrical performance of the device by reducing unwanted charge accumulation and signal delay. This change can result in over 10% improvement in parasitic capacitance, such that the transistor can switch faster and consume less power during operation, which in turn contributes to improving the cell efficiency and performance by more than 10%. In some embodiments, following the creation of the upper and lower air inner spacers 98U′ and 98L′, these air gaps can optionally be filled with a dielectric material. The filling dielectric material can solidify to form dielectric inner spacers, replacing the original upper and lower inner spacers 98U and 98L. The inner spacer last process can allow for flexibility in the design and fabrication of semiconductor devices, providing options to either incorporate air gaps or dielectric materials.

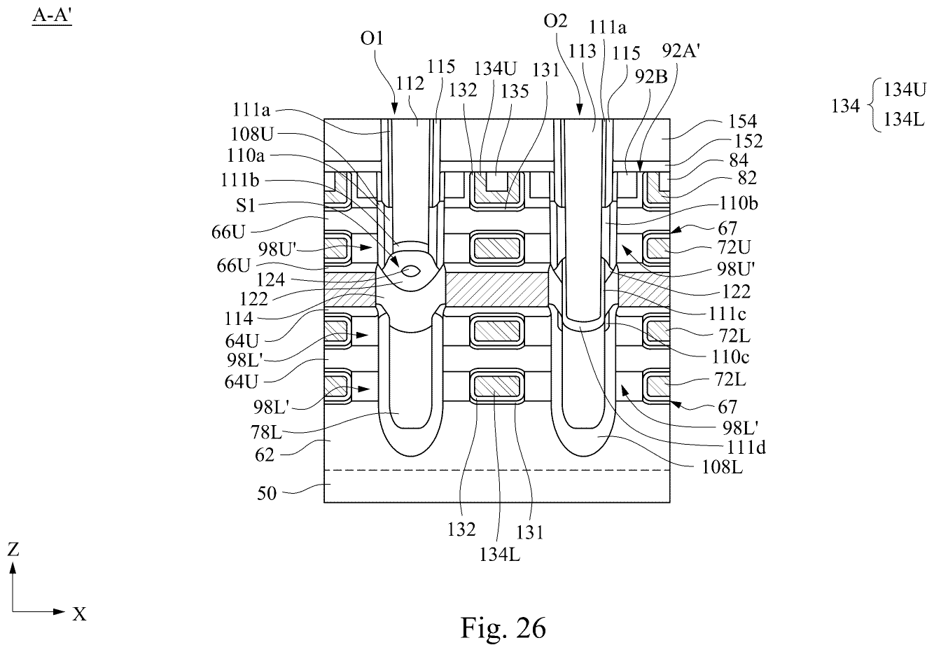

Reference is made to FIGS. 25 and 26. A front-side source/drain contact 112 (see FIG. 26) and a vertical local interconnect 113 (see FIG. 26) can be formed over the upper epitaxial source/drain regions 108U and/or the lower epitaxial source/drain regions 108L through an ILD layer 154 and an etch stop layer (ESL) 152. Specifically, ILD layer 154 can be deposited over the air gate spacers 92A′, the gate spacers 92B, the ILD 124, and the gate electrodes 134 (e.g., the upper gate electrodes 134U). In some embodiments, the ILD layer 154 can be a flowable film formed by a flowable CVD method, which is subsequently cured. In some embodiments, the ILD 154 can be formed of a dielectric material such as PSG, BSG, BPSG, USG, or the like, which may be deposited by any suitable method, such as CVD, PECVD, or the like.

In some embodiments, an etch stop layer (ESL) 152 can be formed between the ILD 154 and the air gate spacers 92A′, the gate spacers 92B, the ILD 124, and the gate electrodes 134 (e.g., the upper gate electrodes 134U). The ESL 152 may include a dielectric material having a high etching selectivity to the dielectric material of the ILD 154, such as silicon nitride, silicon oxide, silicon oxynitride, or the like. The ILD layer 154 and the ESL 152 do not fill in the air gate spacers 92A′ due to the specific design and fabrication processes used to maintain these spaces as air-filled. For example, the air gate spacers 92A′ can be designed to remain unfilled to exploit the low dielectric constant of air, which helps reduce parasitic capacitance. In some embodiments, the ESL 152 can fill the upper part of the air gate spacers 92A′.

Subsequently, as shown in FIG. 25, a first etching process can be performed to form a first front-side opening O1 that extends through the ILD layer 154 and the CESL 152 to expose the upper stress layer 78U, in which the upper stress layer 78U can act as an etch stop layer. The first etching process may be an anisotropic dry etch process, such as a dry etch process (e.g., RIE, a NBE, or the like). Subsequently, the upper stress layer 78U can be removed from the first front-side opening O1 to expose the CESL 122 and/or the ILD layer 124 overlying the isolation dielectric 114. Specifically, a second etching process can be performed through the first front-side opening O1 to remove the upper stress layer 78U, in which the CESL 122 and/or the ILD layer 124 overlying the isolation dielectric 114 can act as an etch stop layer, such that the first front-side opening O1 can expand to inherit the shape of the upper stress layer 78U and self-align with the peripheral upper epitaxial source/drain regions 108U. In some embodiments, the upper stress layer 78U may be made of a material that has a high etching selectivity relative to the upper epitaxial source/drain regions 108U, the CESL 122, and the ILD layer 124. By way of example but not limiting the present disclosure, the etching selectivity, which is the ratio of the etching rate of the upper stress layer 78U to the upper epitaxial source/drain regions 108U, the CESL 122, and the ILD layer 124, is greater than about 10 when the upper stress layer 78U is etched. In some embodiments, the second etching process may be an anisotropic dry etch process, such as a dry etch process (e.g., RIE, a NBE, or the like) and may employ a different etchant than that used in the first etching process.

In some embodiments, the high etch selectivity between the upper stress layer 78U and the upper and lower epitaxial source/drain regions 108U and 108L can facilitate the formation of an inner wrapped wrap-around contact (WAC) and prevent a deep metal-like defined (MD) recess process (see FIG. 26). The high etch selectivity can allow the etching process to selectively remove the upper stress layer 78U while minimally affecting the underlying upper epitaxial source/drain regions 108U. Since the upper stress layer 78U can act as an etch stop, it ensures that the etching does not extend undesirably into the epitaxial source/drain regions 108U, preserving their integrity and function. By controlling the etch stop, the structure for forming the inner WAC, which wraps around the upper epitaxial source/drain regions 108U for enhanced electrical contact and reduced contact resistance, can be maintained.

Subsequently, a dielectric layer 115 can be formed on a sidewall of the first front-side opening O1. Specifically, the dielectric layer 115 can be formed on the sidewall of the first front-side opening O1 that is higher than a position occupied by the upper stress layer 78U. In some embodiments, the dielectric layer 115 may be made of a same material as the isolation dielectric 114, the CESL 122, and/or the CESL 152. In some embodiments, the dielectric layer 115 may be made of a different material than the isolation dielectric 114, the CESL 122, and/or the CESL 152. In some embodiments, the dielectric layer 115 may be made of dielectric material, such as SiO₂, Si₃N₄, SiON, SiOC, SiOCN base dielectric material, or combinations thereof. In some embodiments, the dielectric layer 115 may be made of an oxide, a nitride-based material, such as Si₃N₄, SiON, or a carbon-based material, such as SiC, SiOC, SiOCN, or combinations thereof. In some embodiments, the dielectric layer 115 may be made of a material having a dielectric constant greater than about 9 (e.g., high dielectric constant (high-k) material). For example, the dielectric layer 115 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof.

In some embodiments, a second front-side opening O2 (see FIG. 25) can be formed to extend through the layer 154 and the CESL 152, similarly to the first front-side opening O1 (see FIG. 25). However, a distinction can be an additional third etching process for the second front-side opening O2. This third etching process can etch the CESL 122, the ILD layer 124, and the isolation dielectric 114 to expose the lower epitaxial source/drain regions 108L and the lower stress layer 78L. In some embodiments, the high etch selectivity between the epitaxial source/drain regions 108L and the lower stress layer 78L can prevent the over-etching of the lower epitaxial source/drain regions 108L during the formation of the second front-side opening O2, preventing the formation of excessively deep recesses which could compromise device reliability and performance. In some embodiments, the third etching process may be an anisotropic dry etch process, such as a dry etch process (e.g., RIE, a NBE, or the like) and may employ a different etchant than that used in the second etching process. In some embodiments, during the execution of the third etching process for the second front-side opening O2, the first front-side opening O1 can be covered or masked, ensuring that the integrity of the first front-side opening O1 be maintained while allowing the third etching process to modify the structure around the second front-side opening O2.

As shown in FIG. 26, the front-side source/drain contact 112 can formed in the first front-side opening O1, and the vertical local interconnects 113 can be formed in the second front-side opening O2. Specifically, the front-side source/drain contact 112/vertical local interconnects 113 may be formed to dispose between the upper epitaxial source/drain regions 108U, such that the front-side source/drain contact 112/vertical local interconnects 113 can separate the upper epitaxial source/drain regions 108U. The front-side source/drain contact 112/vertical local interconnects 113 can be physically and electrically coupled to the upper epitaxial source/drain regions 108U. In some embodiments, the vertical local interconnects 113 can further downwardly extend to the lower epitaxial source/drain regions 108L and the lower stress layer 78L. The front-side source/drain contact 112/vertical local interconnects 113 can result in a WAC for the upper epitaxial source/drain regions 108U, as shown in FIG. 26. In some embodiments, the front-side source/drain contact 112 can be interchangeably referred to as a MD pattern. In some embodiments, the vertical local interconnect 113 can be interchangeably referred to as MD local interconnect (MDLI).

The front-side source/drain contact 112 and the vertical local interconnect 113 may be formed by forming a conductive material in the first and second front-side openings O2 and O3. The conductive material may be cobalt, tungsten, copper, a copper alloy, silver, gold, aluminum, nickel, molybdenum, ruthenium, or the like, which may be formed by a deposition process such as PVD, CVD, or the like. A removal process can be then applied to the conductive material to remove excess insulating material over the ILD layer 154. In some embodiments, a planarization process such as a chemical mechanical polish (CMP), an etch-back process, combinations thereof, or the like may be utilized. The planarization process exposes the ILD layer 154 such that top surface of the ILD layer 154 and the conductive material are level after the planarization process is complete.

The front-side source/drain contact 112 and the vertical local interconnect 113 may occupy a majority of the source/drain recesses 94. For example, the front-side source/drain contact 112 can occupy a portion of the upper portion of the source/drain recess 94 that would otherwise be occupied by the upper epitaxial source/drain region 108U, which is formed of doped semiconductor materials. Thus, the front-side source/drain contact 112 can have a larger volume as compared to filling the upper portion of the source/drain recess 94 with an upper epitaxial source/drain region. The front-side source/drain contact 112/the vertical local interconnect 113 can be formed of a metal, which has a smaller resistance than doped semiconductor materials. Forming the front-side source/drain contacts 112/the vertical local interconnect 113 of a metal having a larger volume may decrease the parasitic resistance of the lower nanostructure-FETs, which may improve the performance of the CFETs.

The upper and lower epitaxial source/drain regions 108U and 108L can have smaller volumes as compared to filling the source/drain recesses 94 with epitaxial source/drain regions. The upper and lower epitaxial source/drain regions 108U and 108L can be doped with a large impurity concentration. Doping the upper and lower epitaxial source/drain regions 108U and 108L with large impurity concentrations can help the upper and lower epitaxial source/drain regions 108U and 108L have sufficient quantities of carriers for the upper and lower nanostructure-FETs to operate, even when the upper and lower epitaxial source/drain regions 108U and 108L have smaller volumes.

As shown in FIG. 26, optionally, metal-semiconductor alloy regions 110a can be formed at interfaces between the upper epitaxial source/drain regions 108U and the front-side source/drain contacts 112. Metal-semiconductor alloy regions 110b and 110c can be formed at interfaces between the upper and lower epitaxial source/drain regions 108U and 108L and the vertical local interconnect 113. The metal-semiconductor alloy regions 110a, 110b, and 110c can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like.

The metal-semiconductor alloy regions 110a, 110b, and 110c can be formed before the front-side source/drain contact 112 and the vertical local interconnect 113 by depositing a metal in the source/drain recesses 94 and then performing a thermal anneal process. The metal can be any metal capable of reacting with the semiconductor materials (e.g., silicon, silicon-germanium, germanium, etc.) of the lower epitaxial source/drain regions 108L to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like.

In some embodiments, metal layers can be deposited on various dielectric materials within the semiconductor structure without directly interacting with the semiconductor materials. For example, for the first front-side opening O1, a metal layer 111a can be deposited on the dielectric layer 115, serving as part of the front-side source/drain contact 112. Similarly, a metal layer 111b can be formed on the CESL 122/the isolation dielectric 114. For the second front-side opening O2, the metal layer 111a as in the first front-side opening O1, can be also deposited on the dielectric layer 115 in the second front-side opening O2. A metal layer 111c can be deposited on the CESL 122/the isolation dielectric 114, and a metal layer 111 d can be deposited on the lower stress layer 78L, serving as part of the vertical local interconnects 113. In some embodiments, after the thermal anneal process, a cleaning process, such as a wet clean, may be performed to remove any residual metal from the source/drain recesses 94, such as from surfaces of the lower metal-semiconductor alloy regions 110a, 110b, and 110c.

Reference is made to FIG. 27. Back-side source/drain contacts 118 can be formed over the lower epitaxial source/drain regions 108L through the substrate 50. Specifically, an fourth etching process can be performed to form back-side opening O3 that extends through the substrate 50 to expose the lower stress layer 78L, in which the upper stress layer 78L can act as an etch stop layer. The fourth etching process may be an anisotropic dry etch process, such as a dry etch process (e.g., RIE, a NBE, or the like).

Subsequently, a dielectric layer 125 can be formed on a sidewall of the back-side opening O3. Specifically, the dielectric layer 125 can be formed on the sidewall of the back-side opening O3 that is lower than a position occupied by the lower stress layer 78L. In some embodiments, the dielectric layer 125 can be substantially similar to the dielectric layer 115 in terms of their material and manufacturing methods.

Subsequently, the lower stress layer 78L can be removed from the back-side opening O3 to expose the isolation dielectric 114 and/or the metal layer 111a overlying the vertical local interconnect 113. Specifically, a second etching process can be performed through the back-side openings O3 to remove the lower stress layer 78L, in which the isolation dielectric 114 and/or the metal layer 111d can act as an etch stop layer, such that the back-side openings O3 can expand to inherit the shapes of the lower stress layers 78L and self-align with the peripheral lower epitaxial source/drain regions 108L. In some embodiments, the lower stress layer 78L may be made of a material that has a high etching selectivity relative to the barrier layer 115, the lower epitaxial source/drain regions 108L, and the metal layer 111d. By way of example but not limiting the present disclosure, the etching selectivity, which is the ratio of the etching rate of the lower stress layer 78L to the barrier layer 115, the lower epitaxial source/drain regions 108L, and the metal layer 111d, is greater than about 10 when the lower stress layer 78L is etched. In some embodiments, the second etching process may be an anisotropic dry etch process, such as a dry etch process (e.g., RIE, a NBE, or the like) and may employ a different etchant than that used in the first etching process.

Subsequently, the back-side source/drain contacts 118 can be formed in the back-side openings O3. In some embodiments, the back-side source/drain contacts 118 can be substantially similar to the front-side source/drain contact 112 and the vertical local interconnects 113 in terms of their material and manufacturing methods. Specifically, the back-side source/drain contacts 118 may be formed to dispose between the lower epitaxial source/drain regions 108L, such that the back-side source/drain contact 118 can separate the lower epitaxial source/drain regions 108L. The back-side source/drain contact 118 can be physically and electrically coupled to the lower epitaxial source/drain regions 108L. In some embodiments, the back-side source/drain contact 118 can further extend to metal layer 111d. The back-side source/drain contact 118 can result in a fully wrapped wrap-around contact (WAC) for the upper epitaxial source/drain regions 108L, as shown in FIG. 27. In some embodiments, the back-side source/drain contact 118 can be interchangeably referred to as a back-side metal-like defined (BMD) pattern.

As shown in FIG. 27, optionally, metal-semiconductor alloy regions 116 can be formed at interfaces between the lower epitaxial source/drain regions 108L and the back-side source/drain contacts 118. In some embodiments, the metal-semiconductor alloy regions 116 can be substantially similar to the metal-semiconductor alloy regions 110a, 110b, and 110c in terms of their material and manufacturing methods. In some embodiments, metal layers can be deposited on various dielectric materials within the semiconductor structure without directly interacting with the semiconductor materials. For example, for the back-side opening O3, a metal layer 117 can be deposited on the dielectric layer 115, the metal-semiconductor alloy region 116, the isolation dielectric 114, and/or the metal layer 111d, serving as part of the back-side source/drain contact 118. In some embodiments, after the thermal anneal process, a cleaning process, such as a wet clean, may be performed to remove any residual metal from the back-side opening O3, such as from surfaces of the lower metal-semiconductor alloy region 116.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides several features aimed at enhancing device performance and manufacturability. A dopant layer, such as borosilicate glass layer or phosphosilicate glass layer, can be employed to manage low doping junction diffusion effectively, eliminating the need for proximity push or convex processes and thereby simplifying manufacturing steps. An improvement can be the use of a semiconductive material, such as silicon germanium (SiGe), as an inner spacer for continuous sidewall epitaxial (EPI) growth seeding, which in turn enhances the quality of the epitaxial source/drain layer by maintaining a thin layer with high doping concentrations to control electrical properties. Further improvement can include filling stress material between sidewalls of the epitaxial source/drain layers to maintain channel stress without merging the epitaxial layers, which in turn compensates for loss in channel stress, enhancing the electrical performance of n-type and p-type networks respectively. After the mechanical chemical polishing (CMP) of the Metal Gate (MG), gate spacer and inner spacer can be removed, leading to the creation of air-filled spacer structures, which contribute to over an improvement in cell capacitance. Furthermore, an inner wrap-around contact (WAC), which can be made by the high etch selectivity between the stress material and epitaxial layers, can be formed to reduce contact resistance and prevent deep metal-defined recess processes.

In some embodiments, a method includes forming a fin-shaped structure over a substrate, wherein the fin-shaped structure comprises a first layer stack and a second layer stack over the first layer stack, the first layer stack comprising alternating layers of first channel layers and first semiconductive layers, and the second layer stack comprising alternating layers of alternating second channel layers and second semiconductive layers; forming a dummy gate structure around a channel region of the fin-shaped structure; forming a spacer layer extending across the fin-shaped structure and over a sidewall of the dummy gate structure; replacing the first semiconductive layers with first dielectric layers, and replacing the second semiconductive layers with second dielectric layers; recessing the first dielectric layers to form first inner spacer recesses among the first channel layers, and recessing the second dielectric layers to form second inner spacer recesses among the second channel layers; forming first inner spacer features in the first inner spacer recesses, and second inner spacer features in the second inner spacer recesses; forming a first source/drain feature over the first channel layers, and a second source/drain feature over the second channel layers; removing the dummy gate structure, the first dielectric layers, and the second dielectric layers; forming a first gate structure to wrap around each of the first channel layers, and a second gate structure to wrap around each of the second channel layers; after forming the first and second gate structures, removing the spacer layer to form an air-filled gate spacer. In some embodiments, the method further includes removing the second inner spacer features through the air-filled gate spacer to form a first air-filled inner spacer. In some embodiments, the method further includes removing the first inner spacer features through the air-filled gate spacer and the first air-filled inner spacer to form a second air-filled inner spacer. In some embodiments, the method further includes forming a dielectric material in the first air-filled inner spacer to form a dielectric inner spacer through the air-filled gate spacer. In some embodiments, the spacer layer comprises polymer. In some embodiments, the first and second inner spacer features are epitaxial structures. In some embodiments, the method further includes after recessing the first dielectric layers and before forming the first inner spacer features, conformally forming a dopant layer over the first channel layers and in the first inner spacer recesses; performing an anneal process to diffuse dopants in the dopant layer into the first channel layers. In some embodiments, the dopant layer is a silicon glass layer. In some embodiments, the method further includes after performing the anneal process, removing the dopant layer.

In some embodiments, a method includes forming a first fin over a substrate, wherein the first fin comprises a first bottom semiconductor nanostructure, a first top semiconductor nanostructure, and a first dielectric layer vertically between the first bottom and top semiconductor nanostructures; growing a first bottom epitaxial layer on a sidewall of the first bottom semiconductor nanostructure; forming a bottom stress material on a sidewall of the first bottom epitaxial layer; forming an isolation dielectric over the bottom stress material and the first bottom epitaxial layer; growing a first top epitaxial layer on a sidewall of the first top semiconductor nanostructure; forming a top stress material on a sidewall of the first top epitaxial layer; forming a bottom gate to wrap around the first bottom semiconductor nanostructure, and a top gate to wrap around the first top semiconductor nanostructure; replacing the top stress material with a front-side metal contact. In some embodiments, the method further includes forming a second fin over the substrate and laterally adjacent to the first fin, wherein the second fin comprises a second bottom semiconductor nanostructure, a second top semiconductor nanostructure, and a second dielectric layer vertically between the second bottom and top semiconductor nanostructures; growing a second top epitaxial layer on a sidewall of the second top semiconductor nanostructure, wherein after replacing the top stress material with the front-side metal contact, the front-side metal contact is laterally between the first and second top epitaxial layers. In some embodiments, the method further includes replacing the bottom stress material with a back-side metal contact. In some embodiments, the method further includes forming a silicide layer over the first top epitaxial layer, wherein from a cross-sectional view taken along a lengthwise direction of the first top semiconductor nanostructure, the silicide layer has a length extending along a direction perpendicular to the lengthwise direction of the first top semiconductor nanostructure. In some embodiments, the front-side metal contact has a concave back-side surface. In some embodiments, the isolation dielectric is at a position level with the first dielectric layer, and the isolation dielectric has a concave front-side surface.

In some embodiments, a semiconductor structure includes first, second, third, and fourth transistors and a first metal contact. The first transistor includes a first semiconductor sheet, a first epitaxial source/drain layer on a side of the first semiconductor sheet, and a first gate structure around the first semiconductor sheet. The second transistor is laterally adjacent to the first transistor. The second transistor includes a second semiconductor sheet, a second epitaxial source/drain layer on a side of the second semiconductor sheet, and a second gate structure around the second semiconductor sheet. The third transistor is over the first transistor. The fourth transistor is over the second transistor and laterally adjacent to the third transistor. The first metal contact is laterally between the first and second epitaxial source/drain layers, wherein the first and second epitaxial source/drain layers share the first metal contact. In some embodiments, a metal contact has a bottom lower than a bottom surface of the first semiconductor sheet and a top higher than a top surface of the first semiconductor sheet. In some embodiments, the semiconductor structure further includes a second metal contact. The third transistor comprises a third semiconductor sheet, a third epitaxial source/drain layer on a side of the third semiconductor sheet, and a third gate structure around the third semiconductor sheet, the fourth transistor comprises a fourth semiconductor sheet, a fourth epitaxial source/drain layer on a side of the fourth semiconductor sheet, and a fourth gate structure around the second semiconductor sheet, and the second metal contact laterally between the third and fourth epitaxial source/drain layers. In some embodiments, the first metal contact further extends to a position between the third and fourth transistors, and the third and fourth transistors share the first metal contact. In some embodiments, the semiconductor structure further includes a metal silicide sandwiched between the first epitaxial source/drain layer and the first metal contact. A lateral dimension of the metal silicide is greater than a lateral dimension of the first epitaxial source/drain layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin-shaped structure over a substrate, wherein the fin-shaped structure comprises a first layer stack and a second layer stack over the first layer stack, the first layer stack comprising alternating layers of first channel layers and first semiconductive layers, and the second layer stack comprising alternating layers of alternating second channel layers and second semiconductive layers;
forming a dummy gate structure around a channel region of the fin-shaped structure;
forming a spacer layer extending across the fin-shaped structure and over a sidewall of the dummy gate structure;
replacing the first semiconductive layers with first dielectric layers, and replacing the second semiconductive layers with second dielectric layers;
recessing the first dielectric layers to form first inner spacer recesses among the first channel layers, and recessing the second dielectric layers to form second inner spacer recesses among the second channel layers;
forming first inner spacer features in the first inner spacer recesses, and second inner spacer features in the second inner spacer recesses;
forming a first source/drain feature over the first channel layers, and a second source/drain feature over the second channel layers;
removing the dummy gate structure, the first dielectric layers, and the second dielectric layers;
forming a first gate structure to wrap around each of the first channel layers, and a second gate structure to wrap around each of the second channel layers; and
after forming the first and second gate structures, removing the spacer layer to form an air-filled gate spacer.

2. The method of claim 1, further comprising:
removing the second inner spacer features through the air-filled gate spacer to form a first air-filled inner spacer.

3. The method of claim 2, further comprising:
removing the first inner spacer features through the air-filled gate spacer and the first air-filled inner spacer to form a second air-filled inner spacer.

4. The method of claim 2, further comprising:
forming a dielectric material in the first air-filled inner spacer to form a dielectric inner spacer through the air-filled gate spacer.

5. The method of claim 1, wherein the spacer layer comprises polymer.

6. The method of claim 1, wherein the first and second inner spacer features are epitaxial structures.

7. The method of claim 1, further comprising:
after recessing the first dielectric layers and before forming the first inner spacer features, conformally forming a dopant layer over the first channel layers and in the first inner spacer recesses; and
performing an anneal process to diffuse dopants in the dopant layer into the first channel layers.

8. The method of claim 7, wherein the dopant layer is a silicon glass layer.

9. The method of claim 7, further comprising:
after performing the anneal process, removing the dopant layer.

10. A method, comprising:
forming a first fin over a substrate, wherein the first fin comprises a first bottom semiconductor nanostructure, a first top semiconductor nanostructure, and a first dielectric layer vertically between the first bottom and top semiconductor nanostructures;
growing a first bottom epitaxial layer on a sidewall of the first bottom semiconductor nanostructure;
forming a bottom stress material on a sidewall of the first bottom epitaxial layer;
forming an isolation dielectric over the bottom stress material and the first bottom epitaxial layer;
growing a first top epitaxial layer on a sidewall of the first top semiconductor nanostructure;
forming a top stress material on a sidewall of the first top epitaxial layer;
forming a bottom gate to wrap around the first bottom semiconductor nanostructure, and a top gate to wrap around the first top semiconductor nanostructure; and
replacing the top stress material with a front-side metal contact.

11. The method of claim 10, further comprising:
forming a second fin over the substrate and laterally adjacent to the first fin, wherein the second fin comprises a second bottom semiconductor nanostructure, a second top semiconductor nanostructure, and a second dielectric layer vertically between the second bottom and top semiconductor nanostructures; and
growing a second top epitaxial layer on a sidewall of the second top semiconductor nanostructure, wherein after replacing the top stress material with the front-side metal contact, the front-side metal contact is laterally between the first and second top epitaxial layers.

12. The method of claim 11, further comprising:
replacing the bottom stress material with a back-side metal contact.

13. The method of claim 10, further comprising:
forming a silicide layer over the first top epitaxial layer, wherein from a cross-sectional view taken along a lengthwise direction of the first top semiconductor nanostructure, the silicide layer has a length extending along a direction perpendicular to the lengthwise direction of the first top semiconductor nanostructure.

14. The method of claim 10, wherein the front-side metal contact has a concave back-side surface.

15. The method of claim 10, wherein the isolation dielectric is at a position level with the first dielectric layer, and the isolation dielectric has a concave front-side surface.

16. A semiconductor structure, comprising:
a first transistor, the first transistor comprising a first semiconductor sheet, a first epitaxial source/drain layer on a side of the first semiconductor sheet, and a first gate structure around the first semiconductor sheet;
a second transistor laterally adjacent to the first transistor, the second transistor comprising a second semiconductor sheet, a second epitaxial source/drain layer on a side of the second semiconductor sheet, and a second gate structure around the second semiconductor sheet;
a third transistor over the first transistor;
a fourth transistor over the second transistor and laterally adjacent to the third transistor; and
a first metal contact laterally between the first and second epitaxial source/drain layers, wherein the first and second epitaxial source/drain layers share the first metal contact.

17. The semiconductor structure of claim 16, wherein a metal contact has a bottom lower than a bottom surface of the first semiconductor sheet and a top higher than a top surface of the first semiconductor sheet.

18. The semiconductor structure of claim 16, further comprising:
a second metal contact, wherein the third transistor comprises a third semiconductor sheet, a third epitaxial source/drain layer on a side of the third semiconductor sheet, and a third gate structure around the third semiconductor sheet, the fourth transistor comprises a fourth semiconductor sheet, a fourth epitaxial source/drain layer on a side of the fourth semiconductor sheet, and a fourth gate structure around the second semiconductor sheet, and the second metal contact laterally between the third and fourth epitaxial source/drain layers.

19. The semiconductor structure of claim 16, wherein the first metal contact further extends to a position between the third and fourth transistors, and the third and fourth transistors share the first metal contact.

20. The semiconductor structure of claim 16, further comprising:
a metal silicide sandwiched between the first epitaxial source/drain layer and the first metal contact, wherein a lateral dimension of the metal silicide is greater than a lateral dimension of the first epitaxial source/drain layer.
